(19) United States
(12) Patent Application Publication
(10) Pub. No.: US 2026/0033188 A1
(43) Pub. Date: Jan. 29, 2026

(54) DISPLAY APPARATUS AND ELECTRONIC APPARATUS INCLUDING THE SAME

(71) Applicant: Samsung Display Co., Ltd., Yongin-si (KR)

(72) Inventors: Sujin Kim, Yongin-si (KR); Chulkyu Kang, Yongin-si (KR); Donghyun Kim, Yongin-si (KR); Kimyeong Eom, Yongin-si (KR); Kyonghwan Oh, Yongin-si (KR); Soohong Cheon, Yongin-si (KR); Seonkyoon Mok, Yongin-si (KR); Buyoung Park, Yongin-si (KR); Gaeun Lee, Yongin-si (KR)

(21) Appl. No.: 19/278,500

(22) Filed: Jul. 23, 2025

(30) Foreign Application Priority Data
Jul. 25, 2024 (KR) 10-2024-0098924
Nov. 1, 2024 (KR) 10-2024-0153713

(51) Int. Cl. H10K 59/131

(52) U.S. Cl. CPC H10K 59/131

(57) ABSTRACT

A display apparatus includes: a driving voltage line extending in a first direction; a conductive pattern on the driving voltage line, and at least partially overlapping with the driving voltage line; a driving transistor including: a first semiconductor layer on the conductive pattern, electrically connected to the conductive pattern, and including a channel region; and a first gate electrode on the first semiconductor layer, and overlapping with the channel region; and a data line extending in a second direction perpendicular to the first direction. The driving voltage line includes a shielding portion including a side surface facing the data line in a plan view. In a plan view, a distance between the side surface of the shielding portion and the data line is less than a distance between the conductive pattern and the data line.

### CROSS-REFERENCE TO RELATED APPLICATION

This application claims priority to and the benefit of Korean Provisional Patent Application No. 10-2024-0098924, filed on Jul. 25, 2024, and Korean Patent Application No. 10-2024-0153713, filed on Nov. 1, 2024, in the Korean Intellectual Property Office, the entire disclosures of all of which are incorporated by reference herein.

### BACKGROUND

### 1. Field

Aspects of embodiments of the present disclosure relate to a display apparatus, and an electronic apparatus including the display apparatus.

### 2. Description of the Related Art

Applications of electronic apparatuses including display apparatuses have recently diversified. Moreover, because electronic apparatuses including display apparatuses have become thinner and lighter, their range of use has expanded.

Because electronic apparatuses including display apparatuses are being utilized in various ways, various methods may be used to design the shapes of display panels, and functions that may be connected to or linked to the display apparatuses are increasing.

The above information disclosed in this Background section is for enhancement of understanding of the background of the present disclosure, and therefore, it may contain information that does not constitute prior art.

### SUMMARY

Embodiments of the present disclosure may be directed to a display apparatus having an improved display quality, and an electronic apparatus including the display apparatus. However, the aspects and features of the present disclosure are not limited thereto.

Additional aspects and features will be set forth, in part, in the description that follows, and in part, may be apparent from the description, or may be learned by practicing one or more of the presented embodiments of the present disclosure.

According to one or more embodiments of the present disclosure, a display apparatus includes: a substrate including a display area including a plurality of pixels, and a non-display area located outside the display area; a driving voltage line extending in a first direction on the substrate, and configured to transmit a driving voltage; a conductive pattern on the driving voltage line, and at least partially overlapping with the driving voltage line; a driving transistor including: a first semiconductor layer on the conductive pattern, electrically connected to the conductive pattern, and including a channel region; and a first gate electrode on the first semiconductor layer, and overlapping with the channel region; a first capacitor including a first electrode integral with the first gate electrode, and a second lower electrode overlapping with the first electrode and included in the conductive pattern; a second capacitor including a third electrode included in the driving voltage line, and a fourth electrode overlapping with the third electrode and included in the conductive pattern; and a data line extending in a second direction perpendicular to the first direction. The driving voltage line includes a shielding portion including a side surface facing the data line in a plan view; and in a plan view, a distance between the side surface of the shielding portion and the data line is less than a distance between the conductive pattern and the data line.

In an embodiment, the first capacitor may further include a second upper electrode on the first electrode and electrically connected to the second lower electrode.

In an embodiment, the third electrode may be in at least a portion of the shielding portion.

In an embodiment, the shielding portion may include: a first portion extending in the second direction, and including a side surface facing the data line; a second portion extending in the second direction, and spaced from the first portion in the first direction; and a third portion extending in the first direction, and connecting the first portion to the second portion.

In an embodiment, a distance between the side surface of the first portion of the shielding portion facing the data line and the data line may be less than a distance between the conductive pattern and the data line.

In an embodiment, in a plan view, the shielding portion may be spaced from the channel region of the first semiconductor layer.

In an embodiment, in a plan view, the channel region of the first semiconductor layer may be located between the first portion and the second portion of the shielding portion, and may be spaced from the third portion of the shielding portion.

In an embodiment, the shielding portion may overlap with all of the channel region of the first semiconductor layer.

According to one or more embodiments of the present disclosure, a display apparatus includes: a substrate including: a display area including a first subpixel circuit of a first subpixel and a second subpixel circuit of a second subpixel that are adjacent to each other; and a peripheral area outside the display area; a driving voltage line configured to transmit a driving voltage, and extending in a first direction on the substrate to traverse a first subpixel circuit region including the first subpixel circuit and a second subpixel circuit region including the second subpixel circuit; a first conductive pattern on the driving voltage line in the first subpixel circuit region and at least partially overlapping with the driving voltage line; a second conductive pattern on the driving voltage line in the second subpixel circuit region and at least partially overlapping with the driving voltage line; a first driving transistor in the first subpixel circuit region, and including: a first semiconductor layer on the first conductive pattern, electrically connected to the first conductive pattern, and including a first channel region; and a first gate electrode on the first semiconductor layer, and overlapping with the first channel region; a second driving transistor in the second subpixel circuit region, and including: a second semiconductor layer on the second conductive pattern, electrically connected to the second conductive pattern, and including a second channel region; and a second gate electrode on the second semiconductor layer, and overlapping with the second channel region; a first data line extending in a second direction perpendicular to the first direction, and configured to transmit a data voltage to the first subpixel circuit; and a second data line extending in the second direction, and configured to transmit a data voltage to the second subpixel circuit. The driving voltage line includes a first shielding portion in the first subpixel circuit region and including a first side surface facing the first data line, and a second side surface facing the second data line, in a plan view. In a plan view, a distance between the first side surface of the first shielding portion and the first data line is less than a distance between the first conductive pattern and the first data line, and in a plan view, the first shielding portion is spaced from the first channel region of the first semiconductor layer.

In an embodiment, a distance between the second side surface of the first shielding portion and the second data line may be less than the distance between the first conductive pattern and the second data line.

In an embodiment, the driving voltage line may further include a second shielding portion in the second subpixel circuit region and including a third side surface facing the second data line in a plan view, and a connection portion that connects the first shielding portion to the second shielding portion.

In an embodiment, a distance between the third side surface of the second shielding portion and the second data line may be less than a distance between the second conductive pattern and the second data line.

In an embodiment, a portion of the second data line may overlap with the connection portion, and the second shielding portion may overlap with all of the second channel region of the second semiconductor layer.

In an embodiment, the first shielding portion may include: a first portion extending in the second direction, and including a side surface facing the first data line; a second portion extending in the second direction, spaced from the first portion in the first direction, and including a side surface facing the second data line; and a third portion extending in the first direction, and connecting the first portion to the second portion.

In an embodiment, in a plan view, the first channel region of the first semiconductor layer may be located between the first portion and the second portion of the first shielding portion, and may be spaced from the third portion of the first shielding portion.

In an embodiment, the display apparatus may further include a first capacitor including a first electrode, and a second lower electrode overlapping with the first electrode. The first electrode and the first gate electrode may be integral with each other, and the second lower electrode may be in the first conductive pattern.

In an embodiment, the first capacitor may further include a second upper electrode on the first electrode, and electrically connected to the second lower electrode.

In an embodiment, the display apparatus may further include a second capacitor including a third electrode, and a fourth electrode overlapping with the third electrode. The third electrode may be in the first shielding portion, and the fourth electrode may be in the first conductive pattern.

According to one or more embodiments of the present disclosure, an electronic apparatus includes: a display apparatus; and a housing accommodating the display apparatus. The display apparatus includes: a substrate including a display area including a plurality of pixels, and a non-display area outside the display area; a driving voltage line extending in a first direction on the substrate, and configured to transmit a driving voltage; a conductive pattern on the driving voltage line, and at least partially overlapping with the driving voltage line; a driving transistor including: a first semiconductor layer on the conductive pattern, electrically connected to the conductive pattern, and including a channel region; and a first gate electrode on the first semiconductor layer, and overlapping with the channel region; and a data line extending in a second direction perpendicular to the first direction. The driving voltage line includes a shielding portion including a side surface facing the data line in a plan view, and in a plan view, a distance between the side surface of the shielding portion and the data line is less than a distance between the conductive pattern and the data line.

In an embodiment, the electronic apparatus may further include a processor, and the display apparatus may further include: a controller configured to receive a control signal from the processor, and output a power control signal based on the control signal; and a power supply circuit configured to generate the driving voltage based on the power control signal of the controller. The driving voltage line may be electrically connected to the power supply circuit, and may be configured to receive the driving voltage.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1A is a schematic perspective view of an electronic apparatus according to an embodiment;

FIG. 1B is an exploded perspective view of an electronic apparatus according to an embodiment;

FIG. 2 is a schematic plan view of a display apparatus according to an embodiment;

FIG. 3 is a schematic block diagram of a display apparatus according to an embodiment;

FIG. 4 is an equivalent circuit diagram illustrating a subpixel circuit and a light-emitting diode electrically connected to the subpixel circuit of one subpixel in a display apparatus according to an embodiment;

FIG. 5 is a cross-sectional view of a portion of a display area of a display apparatus according to an embodiment;

FIG. 6 is a plan view illustrating first through third subpixel circuit areas of first through third subpixels of a display apparatus according to an embodiment;

FIGS. 7-11 are plan views showing components of each layer constituting the first through third subpixels according to a stacking order of the display apparatus illustrated in FIG. 6; and

FIG. 12 is a schematic plan view of a driving voltage line, a first conductive pattern, and data lines of the display apparatus illustrated in FIG. 6.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

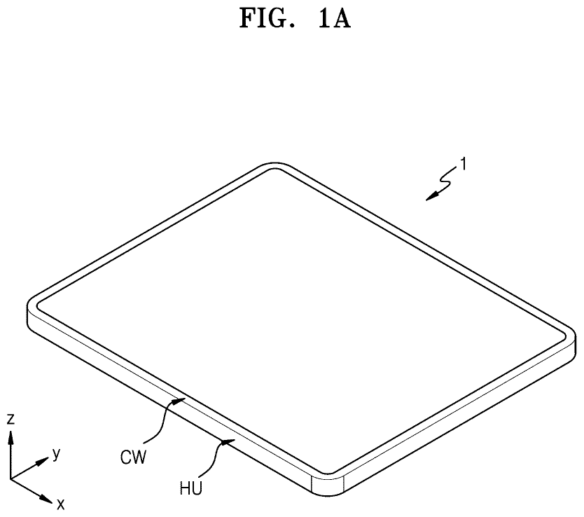

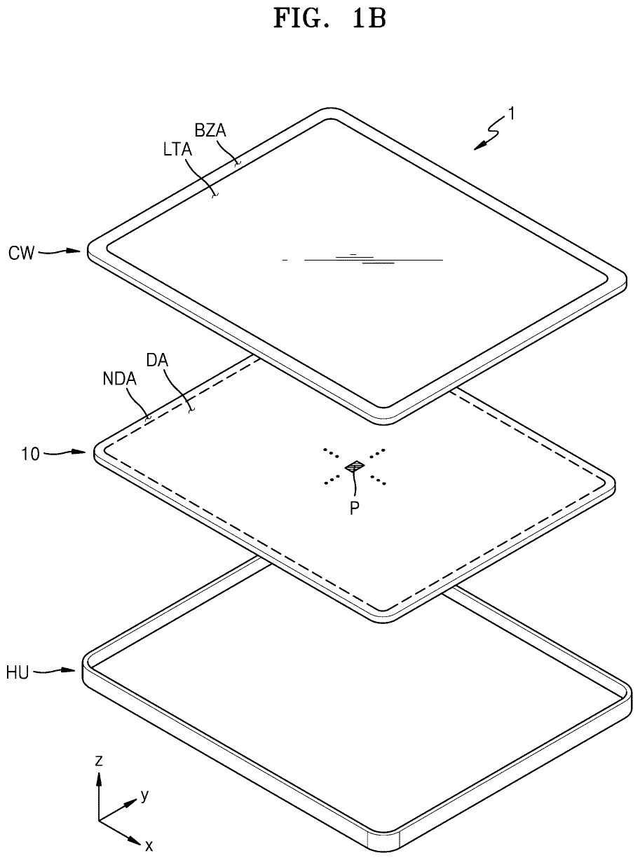

FIG. 1A is a schematic perspective view of an electronic apparatus 1 according to an embodiment. FIG. 1B is an exploded perspective view of the electronic apparatus 1 according to an embodiment.

The electronic apparatus 1 according to an embodiment displays a video and/or a still image, and thus, may be used as a display screen of various suitable products, such as portable electronic apparatuses (e.g., mobile phones, smartphones, tablet personal computers (PCs), mobile communication terminals, electronic notebooks, electronic books, portable multimedia players (PMPs), navigation devices, and ultra mobile PCs (UMPCs)), as well as televisions, notebooks, monitors, advertisement panels, and Internet of things (IoT) devices. The electronic apparatus 1 according to an embodiment may be the entirety or a part of any suitable wearable devices, such as a smart watch, a watch phone, a glasses-type display, and a head mounted display (HMD). The electronic apparatus 1 according to an embodiment may be a center information display (CID) disposed on an instrument panel, a center fascia, or a dashboard of automobiles, a room mirror display that replaces the side mirror of automobiles, a display disposed on the rear surface of a front seat to serve as an entertainment device for back seat passengers of automobiles, a head-up display (HUD) installed at the front of a vehicle or projected on the front window glass, or a computer-generated hologram augmented reality head-up display (CGH AR HUD).

For example, the electronic apparatus 1 may be one of a flat panel display, a curved display, a computer monitor, a medical monitor, a television, a billboard, indoor or outdoor lighting and/or signaling lights, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality or augmented reality display, a vehicle, a video wall including multiple displays tiled together, a theater or stadium screen, a light therapy device, or a signage.

Referring to FIGS. 1A and 1B, the electronic apparatus 1 may display an image in a third direction (e.g., the z direction) perpendicular to or substantially perpendicular to a first direction (e.g., the x direction) and a second direction (e.g., the y direction). The image may include a still image and/or a moving image.

The electronic apparatus 1 may detect a user input applied from an external source. The user input may include various suitable kinds of external inputs, such as a part of a user's body, light, heat, or pressure. The user input may be provided in various suitable forms, and the electronic apparatus 1 may detect the user input applied to a lateral side or a back of the electronic apparatus 1 according to a desired structure of the electronic apparatus 1.

The electronic apparatus 1 may include a cover window CW, a housing HU, and a display apparatus 10. According to an embodiment, the cover window CW and the housing HU may be combined together to form the exterior of the electronic apparatus 1.

The cover window CW may include a light-transmissive area LTA and a bezel area BZA. The light-transmissive area LTA may be an optically transparent area. For example, the light-transmissive area LTA may be an area having a visible light transmittance of about 90% or greater.

The bezel area BZA may define the shape of the light transmissive area LTA. The bezel area BZA may be adjacent to the light-transmissive area LTA, and may surround (e.g., around a periphery of) the light-transmissive area LTA. The bezel area BZA may be an area having a relatively lower light transmittance than that of the light-transmissive area LTA. The bezel area BZA may include an opaque material that shields light. The bezel area BZ may have a desired color (e.g., a specific or predetermined color). The bezel area BZA may be defined by a bezel layer provided separately from a transparent substrate defining the light-transmissive area LTA, or may be defined by an ink layer formed by being inserted into or colored onto the transparent substrate.

The housing HU may be coupled with the cover window CW. The housing HU may accommodate the display apparatus 10. The housing HU may include a rear surface and side surfaces. The cover window CW may be disposed on a front surface of the housing HU. In other words, the cover window CW may be disposed on the housing HU. The housing HU may be coupled with the cover window CW to provide an accommodating space. The display apparatus 10 may be accommodated in the accommodation space provided between the housing HU and the cover window CW.

The housing HU may include a suitable material having a relatively high stiffness. For example, the housing HU may include glass, plastic, or a metal. For example, the housing HU may include a plurality of frames and/or plates including a combination of glass, plastic, or a metal. The housing HU may stably protect the components of the electronic apparatus 1 accommodated in the accommodating space (e.g., an internal space) from external impacts.

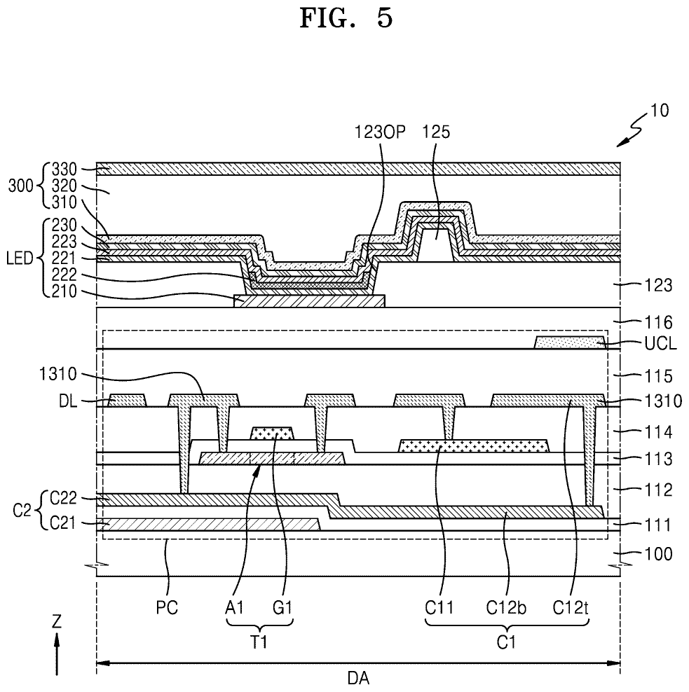

The display apparatus 10 may display an image. The display apparatus 10 may include a display area DA and a non-display area NDA. Because the display apparatus 10 includes a substrate 100 (e.g., see FIG. 5), the substrate 100 may be considered as including the display area DA and the non-display area NDA.

The display area DA may be an active area that is activated by an electrical signal. According to an embodiment, the display area DA may be an area where an image is displayed, and may also be an area where a user input is detected. The display area DA may be an area where a plurality of subpixels P are arranged. The plurality of subpixels P may be repeatedly arranged along the first direction (e.g., the x direction) and the second direction (e.g., the y direction).

The display area DA may at least partially overlap with the light-transmissive area LTA of the cover window CW. For example, the entirety or a portion of the display area DA and the light-transmissive area LTA may overlap with each other. Accordingly, a user may view an image or may provide an external input through the light-transmissive area LTA. However, the present disclosure is not limited thereto. For example, an area where an image is displayed and an area where the user input is detected may be spaced apart (e.g., may be separated) from each other within the display area DA.

The non-display area NDA may at least partially overlap with the bezel area BZA of the cover window CW. The non-display area NDA may be an area covered by the bezel area BZA. The non-display area NDA may be adjacent to the display area DA. The non-display area NDA may be an area where an image is not displayed. A driving circuit, a driving wiring, or the like for driving the display area DA may be disposed in the non-display area NDA.

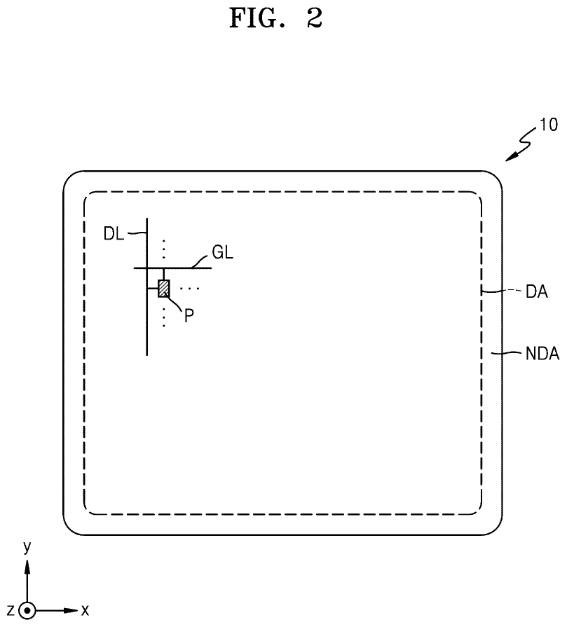

FIG. 2 is a schematic plan view of the display apparatus 10 according to an embodiment.

Referring to FIG. 2, the display apparatus 10 may include the display area DA, and the non-display area NDA outside the display area DA. At least a portion of the display area DA may be surrounded (e.g., around a periphery thereof) by the non-display area NDA.

When viewing the display area DA in a plane view (e.g., a plan view), the display area DA may have a rectangular shape. According to another embodiment, the display area DA may have a polygonal shape (e.g., a triangular shape, a pentagonal shape, or a hexagonal shape), a circular shape, an elliptical shape, an irregular shape, or the like. The display area DA may have a shape having round edge corners. According to an embodiment, the display apparatus 10 may have a display area DA having a shape in which a length in the first direction (e.g., the x direction) thereof is greater than a length in the second direction (e.g., the y direction) thereof, as shown in FIG. 2. According to another embodiment, the display apparatus 10 may have a display area DA having a shape in which the length in the second direction (e.g., the y direction) thereof is greater than the length in the first direction (e.g., the x direction) thereof.

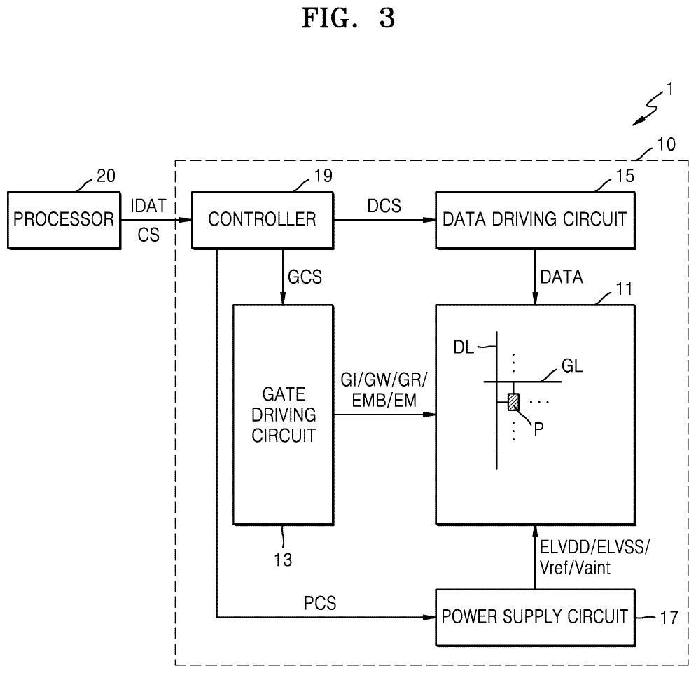

FIG. 3 is a schematic block diagram of the electronic apparatus 1 according to an embodiment.

Referring to FIG. 3, the electronic apparatus 1 may include the display apparatus 10 and a processor 20. The display apparatus 10 according to an embodiment may include a pixel unit (e.g., a pixel area) 11, a gate driving circuit 13, a data driving circuit 15, a power supply circuit 17, and a controller 19.

The pixel unit 11 may be included in the display area DA (e.g., see FIG. 2). Various conductive lines for transmitting electric signals to be applied to the display area DA, external circuits electrically connected to subpixel circuits, and pads to which a printed circuit board (PCB) or a driver integrated circuit (IC) chip is attached may be located in the non-display area NDA (e.g., see FIG. 2). For example, the gate driving circuit 13, the data driving circuit 15, the power supply circuit 17, and the controller 19 may be included in the non-display area NDA.

As shown in FIGS. 2 and 3, a plurality of gate lines GL, a plurality of data lines DL, and a plurality of subpixels P connected thereto may be disposed in the display area DA. The plurality of subpixels P may be arranged in any of various suitable configurations to display an image, such as a stripe configuration, an RGBG configuration (e.g., a PENTILE® configuration, PENTILE® being a duly registered trademark of Samsung Display Co., Ltd.), a diamond configuration, or a mosaic configuration. Each of the plurality of subpixels P may include a subpixel circuit, and a display element (e.g., a light-emitting diode) connected to the subpixel circuit. For example, the display element may include an organic light-emitting diode. The subpixel P may emit, for example, red light, green light, blue light, or white light via the display element. Each of the plurality of subpixels P may be connected to at least one corresponding gate line among the plurality of gate lines GL and a corresponding data line among the plurality of data lines DL.

Each of the plurality of gate lines GL may extend in the first direction (e.g., the x direction or a row direction), and may be connected to the subpixels P located in the same row as each other. Each of the plurality of gate lines GL may transfer a gate signal to the subpixels P in the same row as each other. Each of the plurality of data lines DL may extend in the second direction (e.g., the y direction or a column direction), and may be connected to the subpixels P located in the same column as each other. Each of the plurality of data lines DL may transfer a data signal to each of the corresponding subpixels P in the same column as each other in synchronization with the gate signal.

According to an embodiment, the non-display area NDA may be a non-display area in which no subpixels P are disposed.

The gate driving circuit 13 may be connected to the plurality of gate lines GL, may generate a gate signal in response to a scan control signal GCS from the controller 19, and may sequentially supply the gate signal to the plurality of gate lines GL. The gate line GL may be electrically connected to a gate electrode of a transistor included in a subpixel PX. The gate signal may be a gate control signal for controlling turn-on and turn-off operations of a transistor having a gate connected to a gate line GL. The gate signal may include a gate on-voltage for turning on a transistor, and a gate off-voltage for turning off the transistor. According to an embodiment, the gate on-voltage may be a high level voltage (e.g., a first level voltage) or a low level voltage (e.g., a second level voltage).

Although a subpixel P is illustrated as being connected to one gate line GL in FIGS. 2 and 3, the present disclosure is not limited thereto, and the subpixel P may be connected to two or more gate lines. In this case, the gate driving circuit 13 may supply two or more gate signals having on-voltages that are applied at different timings from each other to the gate lines GL corresponding to the two or more gate signals.

The data driving circuit 15 may be connected to the plurality of data lines DL, and may supply a data signal DATA to the data lines DL in response to a data control signal DCS from the controller 19. A data signal DATA supplied to a data line DL may be supplied to a subpixel P to which a gate signal has been supplied. The data driving circuit 15 may convert input image data input from the controller 19 and having a gray level into a data signal DATA in the form of a voltage or a current.

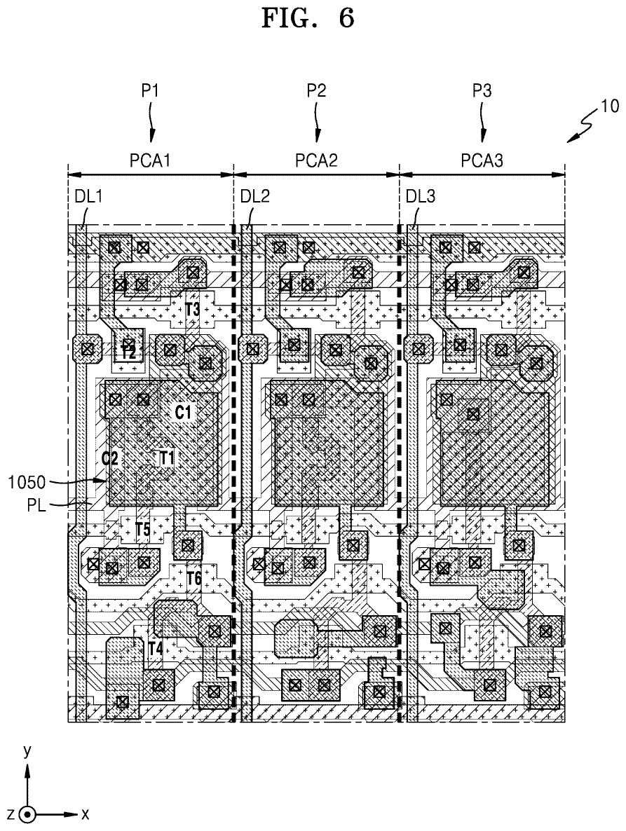

The power supply circuit 17 may generate signals (e.g., a voltage and a current) used for driving the subpixels P in response to a power control signal PCS from the controller 19. The power supply circuit 17 may generate a driving voltage ELVDD and a common voltage ELVSS, and may supply them to the subpixels P. For example, the power supply circuit 17 may generate the driving voltage ELVDD based on the power control signal PCS, and may supply the driving voltage ELVDD to a driving voltage line PL (e.g., see FIG. 6). The driving voltage ELVDD may be a high-level voltage that is provided to a first terminal of a driving transistor connected to a first electrode (e.g., a pixel electrode or an anode) of the display element included in each subpixel P. The common voltage ELVSS may be a low-level voltage that is provided to a second electrode (e.g., an opposite electrode or a cathode) of the display element included in the subpixel P. The power supply circuit 17 may generate a high voltage of a high level and a low voltage of a low level, and may supply them to the gate driving circuit 13.

The controller 19 may receive a control signal CS and input data IDAT from the processor 20 (e.g., an application processor (AP), a graphics processing unit (GPU), a central processing unit (CPU), an image signal processor, a sensor hub processor, or a communication processor). According to an embodiment, the control signal CS may include, but is not limited to, a vertical synchronization signal, a horizontal synchronization signal, an input data enable signal, a master clock signal, and the like. For example, the controller 19 may output the scan control signal GCS, the data control signal DCS, and the power control signal PCS, based on the control signal CS and the input data IDAT received from the processor 20. The scan control signal GCS, the data control signal DCS, and the power control signal PCS generated by the controller 19 may be transmitted to the gate driving circuit 13, the data driving circuit 15, and the power supply circuit 17, respectively. The scan control signal GCS output to the gate driving circuit 13 may include a plurality of clock signals and a gate start signal. The data control signal DCS output to the data driving circuit 15 may include a source start signal and clock signals.

Because the display apparatus 10 includes the substrate 100 (e.g., see FIG. 5), the substrate 100 may be considered as including the display area DA and the non-display area NDA. For example, the subpixels P may be arranged in the display area DA of the substrate 100 (e.g., see FIG. 5). A portion or the entirety of the gate driving circuit 13 may be directly formed in the non-display area NDA of the substrate 100 (e.g., see FIG. 5) during a process of forming the transistors constituting a subpixel circuit in the display area DA of the substrate 100. The data driving circuit 15, the power supply circuit 17, and the controller 19 may be formed as separate IC chips, respectively, or may be formed as a single IC chip, and may be disposed on a flexible printed circuit board (FPCB) electrically connected to a pad disposed on one side of the substrate 100. According to another embodiment, the data driving circuit 15, the power supply circuit 17, and the controller 19 may be directly disposed on the substrate 100 by using a chip on glass (COG) method or a chip on plastic (COP) method.

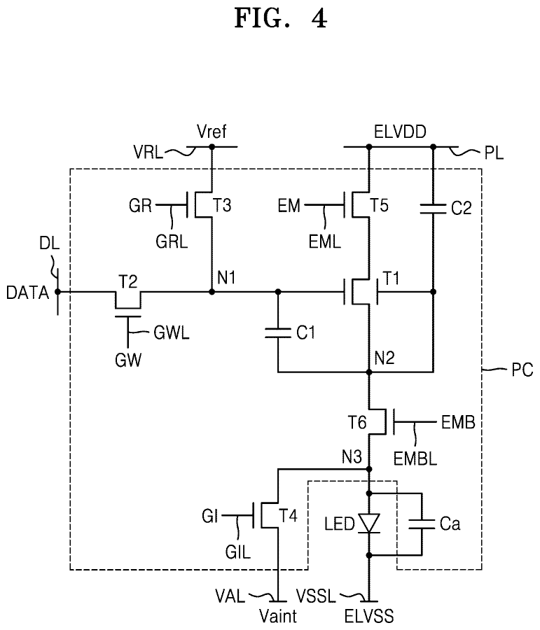

FIG. 4 is an equivalent circuit diagram illustrating a subpixel circuit and a light-emitting diode electrically connected to the subpixel circuit of one subpixel in a display apparatus according to an embodiment.

Referring to FIG. 4, a subpixel circuit PC may be electrically connected to a first gate line GWL that transmits a first gate signal GW, a second gate line GRL that transmits a second gate signal GR, a third gate line EML that transmits a third gate signal EM, a fourth gate line GIL that transmits a fourth gate signal GI, a fifth gate line EMBL that transmits a fifth gate signal EMB, and a data line DL that transmits a data signal DATA. The first gate signal GW may be referred to as a write gate signal, and the first gate line GWL may be referred to as a write gate line. Because light emission of a light-emitting diode LED is controlled by the third gate signal EM and the fifth gate signal EMB, the third gate signal EM and the fifth gate signal EMB may be referred to as emission control signals, and the third gate line EML and the fifth gate line EMBL may be referred to as emission control lines. The subpixel circuit PC may be electrically connected to a driving voltage line PL that transmits a driving voltage ELVDD, a reference voltage line VRL that transmits a reference voltage Vref, and an initializing voltage line VAL that transmits an initializing voltage Vaint.

According to an embodiment, each of a plurality of transistors included in the subpixel circuit PC may be an n-channel MOSFET (NMOS transistor) including an oxide semiconductor layer. However, the present disclosure is not limited thereto, and the transistors are not limited thereto. According to an embodiment, some of the plurality of transistors, for example, such as the first, second, third, fourth, fifth, sixth, seventh, and eighth transistors T1, T2, T3, T4, T5, T6, T7, and T8, may be p-channel MOSFETs (PMOS transistors), and the others of the plurality of transistors may be NMOS transistors. For example, the fifth transistor T5 and/or the sixth transistor T6 from among the plurality of transistors may be PMOS transistors, and the other remaining transistors may be NMOS transistors. For example, a PMOS transistor (e.g., the fifth transistor T5 and/or the sixth transistor T6) may include an inorganic semiconductor (e.g., amorphous silicon or polysilicon) or an organic semiconductor.

The subpixel circuit PC may include the first through sixth transistors T1, T2, T3, T4, T5, and T6, a first capacitor C1, a second capacitor C2, and an auxiliary capacitor Ca. The first transistor T1 may be a driving transistor that outputs a driving current corresponding to the data signal DATA. The second through sixth transistors T2 through T6 may be switching transistors that transmit signals. The first transistor T1 may be referred to as the driving transistor, the second transistor T2 may be referred to as a data writing transistor, the third transistor T3 may be referred to as a compensating transistor, the fourth transistor T4 may be referred to as an initializing transistor, the fifth transistor T5 may be referred to as an operation control transistor, and the sixth transistor T6 may be referred to as a light-emission control transistor.

A first terminal (e.g., a first electrode) and a second terminal (e.g., a second electrode) of each of the first through sixth transistors T1, T2, T3, T4, T5, and T6 may be a source (e.g., a source electrode) or a drain (e.g., a drain electrode) according to the voltages of the first terminal and the second terminal, respectively. For example, according to the voltages of the first terminal and the second terminal, the first terminal may be a drain and the second terminal may be a source, or the first terminal may be a source and the second terminal may be a drain. A node to which a 1-1 gate electrode of the first transistor T1 is connected may be defined as a first node N1, and a node to which the second terminal of the first transistor T1 is connected may be defined as a second node N2.

The first transistor T1 may be connected to the driving voltage line PL and the light-emitting diode LED. The first transistor T1 may be connected between the fifth transistor T5 and the sixth transistor T6. The first transistor T1 may include a first gate electrode, a first terminal, and a second terminal. The second terminal of the first transistor T1 may be connected to the second node N2. The first transistor T1 may include the 1-1 gate electrode connected to the first node N1. The first transistor T1 may further include a 1-2 gate electrode connected to its second terminal. The 1-1 gate electrode and the 1-2 gate electrode may be disposed to face each other at (e.g., in or on) different layers from each other. For example, the 1-1 gate electrode and the 1-2 gate electrode of the first transistor T1 may face each other with a semiconductor layer interposed therebetween. In some embodiments, the first gate electrode of the first transistor may refer to the 1-1 gate electrode involved in turning on and turning off the first transistor T1.

The 1-1 gate electrode of the first transistor T1 may be connected to the second terminal of the second transistor T2, the first terminal of the third transistor T3, and the first capacitor C1. The 1-2 gate electrode of the first transistor T1 may be connected to the first terminal of the sixth transistor T6, the first capacitor C1, and the second capacitor C2. The first terminal of the first transistor T1 may be connected to the driving voltage line PL through the fifth transistor T5, and the second terminal of the first transistor T1 may be connected to a pixel electrode of the light-emitting diode LED through the sixth transistor T6. The first terminal of the first transistor T1 may be connected to the second terminal of the fifth transistor T5. The second terminal of the first transistor T1 may be connected to the first terminal of the sixth transistor T6, the first capacitor C1, and the second capacitor C2. The first transistor T1 may receive the data signal DATA according to a switching operation of the second transistor T2, and may control an amount of a driving current flowing to the light-emitting diode LED.

The second transistor T2 may be connected to the data line DL and the first gate electrode of the first transistor T1. The second transistor T2 may include a second gate electrode connected to the first gate line GWL, a first terminal connected to the data line DL, and a second terminal connected to the first node N1. The second terminal of the second transistor T2 may be connected to the first gate electrode of the first transistor T1, the first terminal of the third transistor T3, and the first capacitor C1. The second transistor T2 may be turned on by the first gate signal GW transmitted to the first gate line GWL to electrically connect the data line DL to the first node N1, and may transmit the data signal DATA received via the data line DL to the first node N1.

The third transistor T3 may be connected to the first gate electrode of the first transistor T1 and the reference voltage line VRL. The third transistor T3 may include a third gate electrode connected to the second gate line GRL, a first terminal connected to the first node N1, and a second terminal connected to the reference voltage line VRL. The first terminal of the third transistor T3 may be connected to the first gate electrode of the first transistor T1, the second terminal of the second transistor T2, and the first capacitor C1. The third transistor T3 may be turned on by the second gate signal GR received via the second gate line GRL to transmit a reference voltage Vref received via the reference voltage line VRL to the first node N1.

The fourth transistor T4 may be connected to the sixth transistor T6 and the initializing voltage line VAL. The fourth transistor T4 may be connected between the light-emitting diode LED and the initializing voltage line VAL. The fourth transistor T4 may include a fourth gate electrode connected to the fourth gate line GIL, a first terminal connected to the third node N3, and a second terminal connected to the initializing voltage line VAL. The first terminal of the fourth transistor T4 may be connected to the second terminal of the sixth transistor T6 and the pixel electrode of the light-emitting diode LED. The fourth transistor T4 may be turned on by the fourth gate signal GI received via the fourth gate line GIL to transmit the initializing voltage Vaint received via the initializing voltage line VAL to the third node N3, and may initialize the pixel electrode (e.g., an anode) of the light-emitting diode LED.

The fifth transistor T5 may be connected to the driving voltage line PL and the first transistor T1. The fifth transistor T5 may include a fifth gate electrode connected to the third gate line EML, a first terminal connected to the driving voltage line PL, and a second terminal connected to the first terminal of the first transistor T1. The fifth transistor T5 may be turned on or turned off according to the third gate signal EM received via the third gate line EML.

The sixth transistor T6 may be connected to the first transistor T1 and the light-emitting diode LED. The sixth transistor T6 may be connected between the second node N2 and the third node N3. The sixth transistor T6 may include a sixth gate electrode connected to the fifth gate line EMBL, a first terminal connected to the second node N2, and a second terminal connected to the third node N3. The first terminal of the sixth transistor T6 may be connected to the second terminal of the first transistor T1, the first capacitor C1, and the second capacitor C2. The second terminal of the sixth transistor T6 may be connected to the first terminal of the fourth transistor T4 and the pixel electrode of the light-emitting diode LED. The sixth transistor T6 may be turned on or turned off according to the fifth gate signal EMB received via the fifth gate line EMBL.

The first capacitor C1 may be connected between the first gate electrode of the first transistor T1 and the second terminal of the first transistor T1. A first electrode of the first capacitor C1 may be connected to the first node N1, and a second electrode thereof may be connected to the second node N2. The first electrode of the first capacitor C1 may be connected to the first gate electrode of the first transistor T1, the second terminal of the second transistor T2, and the first terminal of the third transistor T3. The second electrode of the first capacitor C1 may be connected to the second terminal and the 1-2 gate electrode of the first transistor T1, the second electrode of the second capacitor C2, and the first terminal of the sixth transistor T6. The first capacitor C1, which may be a storage capacitor, may store a threshold voltage of the first transistor T1 and a voltage corresponding to the data signal DATA.

When the third transistor T3 and the fifth transistor T5 are turned on, the first transistor T1 may be turned on. When a voltage of the second terminal of the first transistor T1 drops to a difference between the reference voltage (Vref) and the threshold voltage (Vth1) of the first transistor T1 (e.g., Vref−Vth1), the first transistor T1 may be turned off, and a voltage corresponding to the threshold voltage (Vth1) of the first transistor T1 may be stored in the first capacitor C1, so that the threshold voltage (Vth1) of the first transistor T1 may be compensated for.

The second capacitor C2 may be connected between the driving voltage line PL and the second node N2. A first electrode of the second capacitor C2 may be connected to the driving voltage line PL. The second electrode of the second capacitor C2 may be connected to the second terminal and the 1-2 gate electrode of the first transistor T1, the second electrode of the first capacitor C1, and the first terminal of the sixth transistor T6.

A capacitance of each of the first capacitor C1 and the second capacitor C2 may vary according to a color of light emitted by the light-emitting diode LED.

The auxiliary capacitor Ca may be electrically connected to the sixth transistor T6, a sustain voltage line VSSL, and the pixel electrode of the light-emitting diode LED. The auxiliary capacitor Ca stores and maintains a voltage corresponding to a difference between a voltage of the pixel electrode of the light-emitting diode LED and a voltage of the sustain voltage line VSSL, thereby preventing or substantially preventing a black brightness from rising when the sixth transistor T6 is turned off. The light-emitting diode LED may be connected to the first transistor T1

through the sixth transistor T6. The light-emitting diode LED may include the pixel electrode (e.g., the anode) connected to the third node N3, and an opposite electrode (e.g., a cathode) facing the pixel electrode. The opposite electrode may receive a common voltage ELVSS. According to an embodiment, the opposite electrode (e.g., the cathode) may be electrically connected to the sustain voltage line VSSL that extends into a display area to provide the common voltage ELVSS. The driving current output by the first transistor T1 may flow through the light-emitting diode LED by the turned-on fifth transistor T5 and the turned-on sixth transistor T6, and the light-emitting diode LED may emit light having a brightness corresponding to the magnitude of the driving current.

Although a case where the subpixel circuit PC includes six transistors is illustrated in FIG. 4, the present disclosure is not limited thereto. According to another embodiment, the subpixel circuit PC may include seven transistors. According to another embodiment, the number of transistors in the subpixel circuit PC may be 5 or less, or may be 8 or more.

FIG. 5 is a cross-sectional view of a portion of the display area DA of the display apparatus 10 according to an embodiment.

Referring to FIG. 5, the display apparatus 10 includes a light-emitting diode LED arranged in the display area DA. The light-emitting diode LED may be disposed on the substrate 100, and a subpixel circuit PC may be disposed between the substrate 100 and the light-emitting diode LED. According to an embodiment, FIG. 5 illustrates a first transistor T1, a first capacitor C1, and a second capacitor C2, which are some of the components of the subpixel circuit PC as described above.

The substrate 100 may include a glass material or a polymer resin. According to an embodiment, the substrate 100 may have a structure in which a base layer including a polymer resin and a barrier layer including an inorganic insulating material, such as silicon oxide or silicon nitride, are alternately stacked. The polymer resin may include polyethersulfone, polyarylate, polyetherimide, polyethylene naphthalate, polyethylene terephthalate, polyphenylene sulfide, polyimide, polycarbonate, cellulose triacetate, or cellulose acetate propionate, for example.

A first electrode C21 of the second capacitor C2 may be disposed on the substrate 100. The first electrode C21 of the second capacitor C2 may include a conductive material such as a metal, for example, such as molybdenum (Mo), aluminum (Al), copper (Cu), and/or titanium (Ti), and may have a single-layer structure or a multi-layered structure including one or more of the aforementioned materials.

A first insulating layer 111 may be disposed on the first electrode C21 of the second capacitor C2. The first insulating layer 111 may include an inorganic insulating material, such as silicon oxide, silicon nitride, or silicon oxynitride, and may have a single layer or multiple layers including one or more of the inorganic insulating materials.

A second electrode C22 of the second capacitor C2 and a second lower electrode C12b of the first capacitor C1 may be disposed on the first insulating layer 111. According to an embodiment, the second electrode C22 of the second capacitor C2 and second lower electrode C12b of the first capacitor C1 may be integrally included by being connected to each other. The second electrode C22 of the second capacitor C2 and second lower electrode C12b of the first capacitor C1 may include a conductive material such as a metal, for example, such as molybdenum (Mo), aluminum (Al), copper (Cu), and/or titanium (Ti), and may have a single-layer structure or a multi-layered structure including one or more of the aforementioned materials.

A second insulating layer 112 may be disposed on the second electrode C22 of the second capacitor C2 and second lower electrode C12b of the first capacitor C1. The second insulating layer 112 may include an inorganic insulating material, such as silicon oxide, silicon nitride, or silicon oxynitride, and may have a single layer or multiple layers including one or more of the inorganic insulating materials. The second insulating layer 112 may be a kind of a buffer layer that prevents or substantially prevents impurities from penetrating into a transistor, for example, such as into the first transistor T1.

As used herein, the first electrode C21 and the second electrode C22 of the second capacitor C2 may be referred to as a third electrode and a fourth electrode, respectively.

A semiconductor layer may be disposed on the second insulating layer 112. For example, FIG. 5 illustrates that a first semiconductor layer A1 of the first transistor T1 is disposed on the second insulating layer 112. The first semiconductor layer A1 may include a channel region, and a source region and a drain region respectively arranged on opposite sides of the channel region. The first semiconductor layer A1 may include an oxide of at least one of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), or zinc (Zn). For example, the first semiconductor layer A1 may be an InSnZnO (ITZO) semiconductor layer, an InGaZnO (IGZO) semiconductor layer, or the like. At least a portion of the first semiconductor layer A1 may undergo a conductivization (e.g., may be made conductive) by a plasma treatment or the like.

The first gate electrode G1 may overlap with the channel region of the first semiconductor layer A1 with a third insulating layer 113 therebetween. The second electrode C22 of the second capacitor C2 may face the first gate electrode G1 with the first semiconductor layer A1 therebetween. The second electrode C22 of the second capacitor C2 may be a lower gate electrode of the first transistor T1, and the first gate electrode G1 may be an upper gate electrode of the first transistor T1. The first gate electrode G1 may include a conductive material including molybdenum (Mo), aluminum (Al), copper (Cu), titanium (Ti), and/or the like, and may have a single-layer structure or a multi-layered structure including one or more of the aforementioned materials. The third insulating layer 113 may include an inorganic insulating material, such as silicon oxide, silicon nitride, or silicon oxynitride, and may have a single-layer structure or a multi-layered structure including one or more of the inorganic insulating materials.

The first electrode C11 of the first capacitor C1 may overlap with the second lower electrode C12b with the second insulating layer 112 and the third insulating layer 113 therebetween. In FIG. 5, the first electrode C11 of the first capacitor C1 is illustrated as being spaced apart (e.g., separated) from the first gate electrode G1. However, the present disclosure is not limited thereto, and the first electrode C11 of the first capacitor C1 may be integrally provided with, by being connected to, the first gate electrode G1.

The first electrode C11 of the first capacitor C1 may include a conductive material including molybdenum (Mo), aluminum (Al), copper (Cu), titanium (Ti), and/or the like, and may have a single-layer structure or a multi-layered structure including one or more of the aforementioned materials.

A fourth insulating layer 114 may be disposed on the first electrode C11 of the first capacitor C1 and the first gate electrode G1. The fourth insulating layer 114 may include an inorganic insulating material, such as silicon oxide, silicon nitride, or silicon oxynitride, and may have a single-layer structure or a multi-layered structure including one or more of the inorganic insulating materials.

The data line DL, a first connection pattern 1310, and a second upper electrode C12t of the first capacitor C1 may be disposed on the fourth insulating layer 114. The first connection pattern 1310 may connect the first semiconductor layer A1 of the first transistor T1 to the second electrode C22 of the second capacitor C2. The second upper electrode C12t of the first capacitor C1 may be at least a portion of the first connection pattern 1310. The second upper electrode C12t of the first capacitor C1 may overlap with the second lower electrode C12b of the first capacitor C1 with the second insulating layer 112, the third insulating layer 113, and the fourth insulating layer 114 therebetween. The second upper electrode C12t of the first capacitor C1 may be connected to the second lower electrode C12b of the first capacitor C1 through a contact hole that passes through the second insulating layer 112, the third insulating layer 113, and the fourth insulating layer 114. The second upper electrode C12t of the first capacitor C1 may overlap with the first electrode C11 of the first capacitor C1 with the fourth insulating layer 114 therebetween. The data line DL, the first connection pattern 1310, and the second upper electrode C12t of the first capacitor C1 may include a conductive material including molybdenum (Mo), aluminum (Al), copper (Cu), titanium (Ti), and/or the like, and may have a single-layer structure or a multi-layered structure including one or more of the aforementioned materials.

A fifth insulating layer 115 may be disposed on the data line DL, the first connection pattern 1310, and the second upper electrode C12t of the first capacitor C1, and may include an organic insulating material, such as acrylic, benzocyclobutene (BCB), polyimide, or hexamethyldisiloxane (HMDSO).

An upper conductive layer UCL may be disposed on the fifth insulating layer 115. An upper conductive pattern disposed at (e.g., in or on) the same layer as that of the upper conductive layer UCL may be connected to the light-emitting diode LED, and the upper conductive pattern may be connected to a transistor (e.g., the sixth transistor T6 in FIG. 4) of the subpixel circuit PC. In some embodiments, other voltage lines, for example, such as the sustain voltage line VSSL (e.g., see FIG. 4), may be disposed at (e.g., in or on) the same layer as that of the upper conductive layer UCL, for example, such as on the fifth insulating layer 115, in another view different from that illustrated in FIG. 5. The upper conductive layer UCL may include a conductive material including molybdenum (Mo), aluminum (Al), copper (Cu), titanium (Ti), and/or the like, and may have a single-layer structure or a multi-layered structure including one or more of the aforementioned materials.

A sixth insulating layer 116 may be disposed on the upper conductive layer UCL, and may include an organic insulating material, such as acryl, benzocyclobutene (BCB), polyimide, or hexamethyldisiloxane (HMDSO).

The light-emitting diode LED may include a pixel electrode 210, an emission layer 222, and an opposite electrode 230.

The pixel electrode 210 may be disposed on the sixth insulating layer 116. The pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a suitable compound thereof. According to another embodiment, the pixel electrode 210 may further include a conductive oxide layer above/below the reflective layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). According to an embodiment, the pixel electrode 210 may have a three-layered structure of ITO/Ag/ITO layers.

A bank layer 123 may be disposed on the pixel electrode 210. The bank layer 123 may include an opening 123OP that overlaps with the pixel electrode 210, and the bank layer 123 may cover an edge of the pixel electrode 210. The bank layer 123 may include an organic insulating material. According to some embodiments, the bank layer 123 may include a light-transmissive organic insulating layer. According to another embodiment, the bank layer 123 may include an organic insulating material including a light-shielding material. According to some embodiments, the bank layer 123 may include a polyimide (PI)-based binder, and a pigment obtained by mixing a red color, a green color, and a blue color with each other. As another example, the bank layer 123 may include a cardo-based binder resin, and a mixture of a lactam-based black pigment and a blue pigment. As another example, the bank layer 123 may include carbon black. The bank layer 123 may improve the contrast of the display apparatus 10.

A spacer 125 may be disposed on the bank layer 123. The spacer 125 may include a material different from that included in the bank layer 123. In other words, the bank layer 123 and the spacer 127 may include different materials from each other. For example, the bank layer 123 may include a negative photosensitive material and the spacer 127 may include a positive photosensitive material, and they may be formed through separate mask processes, respectively. According to another embodiment, the spacer 125 may include the same material as that of the bank layer 123, and may be formed together with the bank layer 123 in the same mask process (e.g., a halftone mask process).

The emission layer 222 may include a high molecular organic material or a low molecular organic material that emits light of a desired color (e.g., a certain or predetermined color). The emission layer 222 may include a suitable material that emits red light, green light, or blue light according to the light-emitting diode LED.

A functional layer may be further included below and/or above the emission layer 222. For example, a first functional layer 221 may be interposed between the pixel electrode 210 and the emission layer 222, and a second functional layer 223 may be interposed between the emission layer 222 and the opposite electrode 230. The first functional layer 221 may include a hole transport layer and/or a hole injection layer. The second functional layer 223 may include an electron transport layer and/or an electron injection layer.

The opposite electrode 230 may include a conductive material having a low work function. For example, the opposite electrode 230 may include a (semi) transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or a suitable alloy thereof. As another example, the opposite electrode 230 may further include another layer, such as ITO, IZO, ZnO, or In₂O₃, on the (semi) transparent layer including any of the above-described materials.

Unlike pixel electrodes 210 that are individually formed from each other to correspond to the light-emitting diodes LEDs, respectively, the opposite electrode 230 may extend to correspond to the pixel electrodes 210. For example, a pixel electrode 210 of one light-emitting diode LED and a pixel electrode 210 of another light-emitting diode LED may be spaced apart (e.g., separated) from each other, but the opposite electrode 230 overlapping with the pixel electrodes 210 may extend to cover the pixel electrodes 210.

An encapsulation layer 300 may be disposed on the light-emitting diodes LED, and may include at least one inorganic encapsulation layer and at least one organic encapsulation layer. According to an embodiment, FIG. 5 illustrates that the encapsulation layer 300 includes a first inorganic encapsulation layer 310, an organic encapsulation layer 320, and a second inorganic encapsulation layer 330.

The first and second inorganic encapsulation layers 310 and 330 may include at least one inorganic insulating material from among aluminum oxide, titanium oxide, tantalum oxide, hafnium oxide, zinc oxide, silicon oxide, silicon nitride, and/or silicon oxynitride. The first inorganic encapsulation layer 310 and the second inorganic encapsulation layer 330 may be a single layer or multiple layers including one or more of the aforementioned materials. The organic encapsulation layer 320 may include a polymer-based material. Examples of the polymer-based material may include an acrylic resin, an epoxy-based resin, polyimide, and polyethylene. According to an embodiment, the organic encapsulation layer 320 may include acrylate.

FIG. 6 is a plan view illustrating first through third subpixel circuit areas of first through third subpixels of a display apparatus according to an embodiment. FIG. 6 may be a planar structure (e.g., a plan view) of a subpixel circuit PC of the display apparatus 10 described above with reference to FIGS. 4 and 5. FIG. 6 illustrates the first, second, third, fourth, fifth, and sixth transistors T1, T2, T3, T4, T5, and T6, the first capacitor C1, and the second capacitor C2 of each of a first subpixel P1, a second subpixel P2, and a third subpixel P3.

Referring to FIG. 6, a first subpixel circuit area PCA1 in which a first subpixel circuit of the first subpixel P1 is disposed, a second subpixel circuit area PCA2 in which a second subpixel circuit of the second subpixel P2 is disposed, and a third subpixel circuit area PCA3 in which a third subpixel circuit of the third subpixel P3 is disposed may be arranged adjacent to one another along a first direction (e.g., the x direction).

According to an embodiment, in a plan view, the first transistor T1 and the first capacitor C1 may overlap with each other in a third direction (e.g., the z direction).

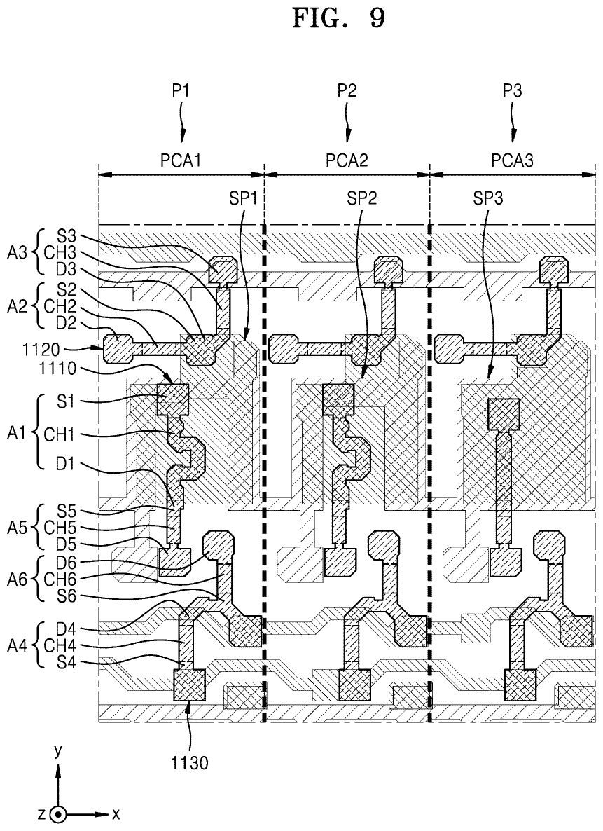

According to an embodiment, in a plan view, a first channel region CH1 (e.g., see FIG. 9) of a first semiconductor layer A1 of the first transistor T1 may not overlap with the second capacitor C2 in each of the first subpixel P1 and the second subpixel P2. According to an embodiment, in a plan view, the first channel region CH1 (e.g., see FIG. 9) of the first semiconductor layer A1 of the first transistor T1 may overlap with the second capacitor C2 in the third subpixel P3.

According to an embodiment, in a plan view, the second transistor T2 and the third transistor T3 may be arranged on one side of the first transistor T1, and the fourth transistor T4, the fifth transistor T5, and the sixth transistor T6 may be arranged on another side (e.g., an opposite side) of the first transistor T1. For example, in a plan view, the second transistor T2 and the third transistor T3 may be arranged on an upper side of the first transistor T1, and the fourth transistor T4, the fifth transistor T5, and the sixth transistor T6 may be arranged on a lower side of the first transistor T1.

A first data line DL1 electrically connected to the first subpixel circuit of the first subpixel P1 may be disposed in the first subpixel circuit area PCA1, a second data line DL2 electrically connected to the second subpixel circuit of the second subpixel P2 may be disposed in the second subpixel circuit area PCA2, and a third data line DL3 electrically connected to a third subpixel circuit of the third subpixel P3 may be disposed in the third subpixel circuit area PCA3.

In a plan view, a side surface of the driving voltage line PL facing a data line (e.g., the first, second, and third data lines DL1, DL2, and DL3) may be disposed closer to the data line than a side surface of a first conductive pattern 1050 facing the data line.

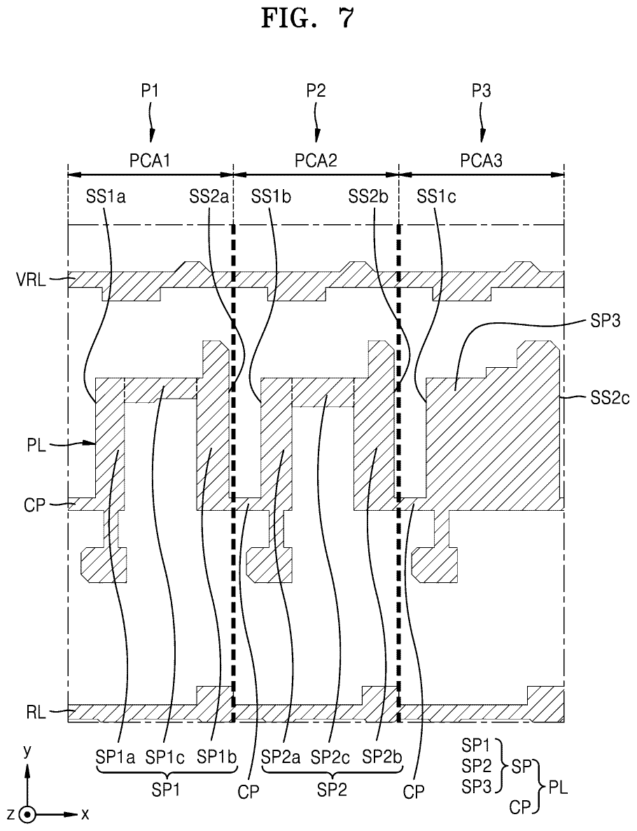

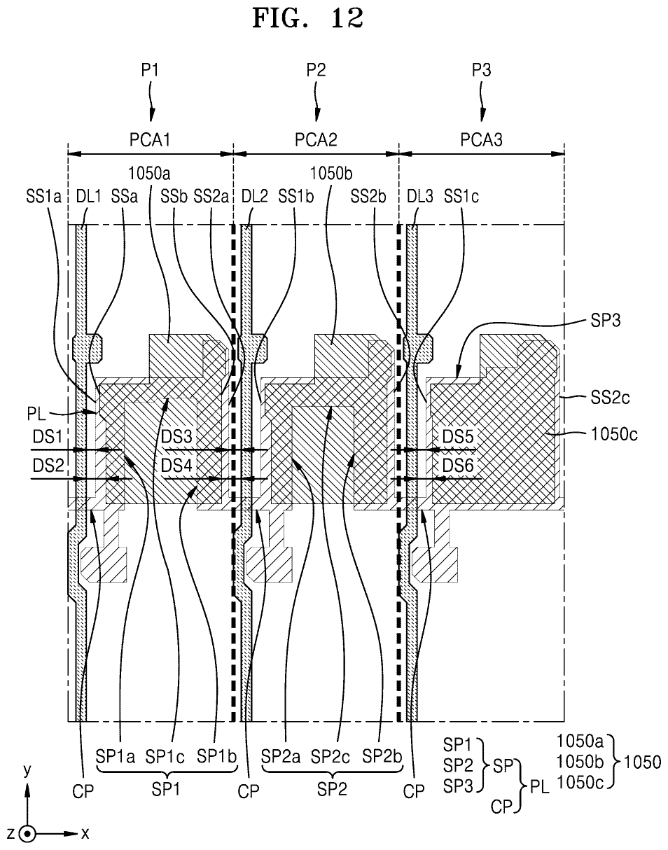

FIGS. 7 through 11 are plan views showing the components of each layer constituting the first through third subpixels P1 through P3 according to a stacking order of the display apparatus 10 illustrated in FIG. 6. FIG. 12 is a schematic plan view of the driving voltage line PL, the first conductive pattern 1050, and the data lines (e.g., the first data line DL1, the second data line DL2, and the third data line DL3) of the display apparatus 10 illustrated in FIG. 6.

Referring to FIG. 7, the driving voltage line PL, the reference voltage line VRL, and a repair line RL may be arranged on the substrate 100 (e.g., see FIG. 5).

Each of the driving voltage line PL, the reference voltage line VRL, and the repair line RL may extend in the first direction (e.g., the x direction) to traverse the first subpixel circuit area PCA1, the second subpixel circuit area PCA2, and the third subpixel circuit area PCA3. The driving voltage line PL may be electrically connected to the power supply circuit 17 (e.g., see FIG. 3). Based on the power control signal PCS (e.g., see FIG. 3) received from the controller 19, the driving voltage line PL may receive the driving voltage ELVDD generated by the power supply circuit 17, and may transmit the driving voltage ELVDD to each subpixel.

Referring to FIGS. 7 and 12 together, in a plan view, the driving voltage line PL may include a shielding portion including a side surface facing the data line (e.g., the first data line DL1, the second data line DL2, or the third data line DL3). The driving voltage line PL may include a first shielding portion SP1 disposed in the first subpixel circuit area PCA1, a second shielding portion SP2 disposed in the second subpixel circuit area PCA2, and a third shielding portion SP3 disposed in the third subpixel circuit area PCA3.

In a plan view, the first shielding portion SP1 may include a first side surface SS1a facing the first data line DL1, and a second side surface SS2a facing the second data line DL2. In a plan view, the second shielding portion SP2 may include a first side surface SS1b facing the second data line DL2, and a second side surface SS2b facing the third data line DL3. In a plan view, the third shielding portion SP3 may include a first side surface SS1c facing the third data line DL3, and a second side surface SS2c opposite to the first side surface SS1c.

The first shielding portion SP1 may include a first portion SP1a extending in a second direction (e.g., the y direction) perpendicular to the first direction, a second portion SP1b extending in the second direction (e.g., the y direction) and spaced apart from the first portion SP1a in the first direction (e.g., the x direction), and a third portion SP1c connecting the first portion SP1a to the second portion SP1b. In a plan view, the first portion SP1a of the first shielding portion SP1 may include the first side surface SS1a facing the first data line DL1. In a plan view, the second portion SP1b of the first shielding portion SP1 may include the second side surface SS1b facing the second data line DL2. The first shielding portion SP1 may have, for example, an omega shape.

The second shielding portion SP2 may include a first portion SP2a extending in the second direction (e.g., the y direction) intersecting or crossing the first direction, a second portion SP2b extending in the second direction (e.g., the y direction) and spaced apart from the second portion SP2b in the first direction (e.g., the x direction), and a third portion SP2c connecting the first portion SP2a to the second portion SP2b. The first portion SP2a of the second shielding portion SP2 may include the first side surface SS1b facing the second data line DL2. The second portion SP2b of the second shielding portion SP2 may include the second side surface SS2b facing the third data line DL3. The second shielding portion SP2 may have, for example, an omega shape.

According to an embodiment, each of the first shielding portion SP1 and the second shielding portion SP2 may overlap with the first conductive pattern 1050 to form the second capacitor C2, and may have an omega shape extending to overlap with an edge of the first conductive pattern 1050, thereby sufficiently securing the capacitance of the second capacitor C2.

According to an embodiment, the third shielding portion SP3 may have a larger area than that of each of the first shielding portion SP1 and/or the second shielding portion SP2. The third shielding portion SP3 may have, for example, an approximately polygonal shape.

The driving voltage line PL may further include a connection portion CP connecting shielding portions adjacent to each other in the first direction (e.g., the x direction) to each other. For example, the first shielding portion SP1 and the second shielding portion SP2 may be connected to each other by the connection portion CP. For example, the second shielding portion SP2 and the third shielding portion SP3 may be connected to each other by the connection portion CP.

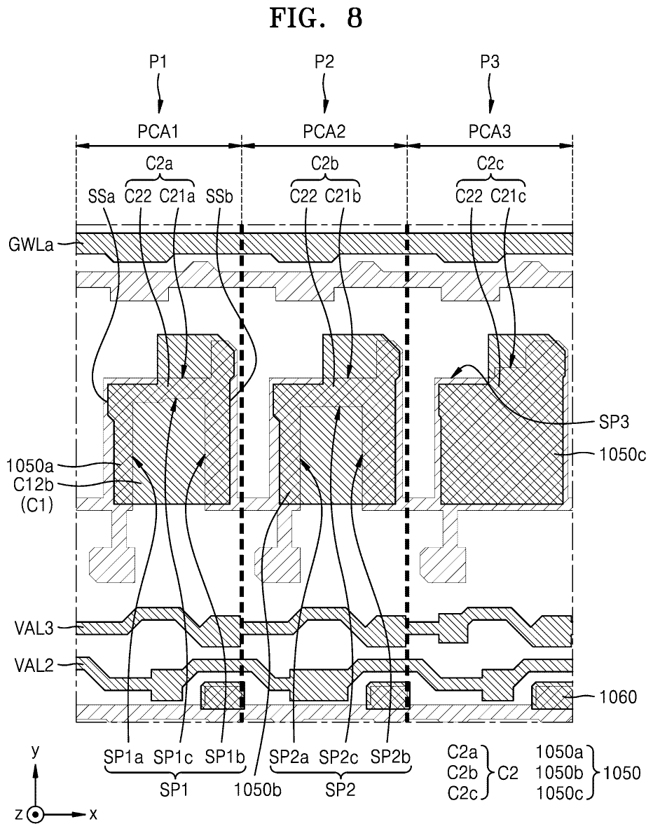

The driving voltage line PL may include the first electrode C21 (e.g., see FIG. 5) of the second capacitor C2. For example, the driving voltage line PL may include a first electrode C21a (e.g., see FIG. 8) of a second capacitor C2a of the first subpixel P1, a first electrode C21b of a second capacitor C2b of the second subpixel P2, and a first electrode C21c of a second capacitor C2c of the third subpixel P3. For example, the first shielding portion SP1 may include the first electrode C21a (e.g., see FIG. 8) of the second capacitor C2a of the first subpixel P1, the second shielding portion SP2 may include the first electrode C21b of the second capacitor C2b of the second subpixel P2, and the third shielding portion SP3 may include the first electrode C21c of the second capacitor C2c of the third subpixel P3. The first, second, and third electrodes C21a, C21b, and C21c (e.g., see FIG. 8) of the respective second capacitors C2a, C2b, and C2c of the first, second, and third subpixels P1, P2, and P3 may be integrally connected to each other.

The repair line RL may be a spare line that may be used when a defect occurs in signal lines or voltage lines included in the subpixel circuits of the first, second, and third subpixels P1, P2, and P3.

The driving voltage line PL, the reference voltage line VRL, and the repair line RL may include the same material as each other. Each of the driving voltage line PL, the reference voltage line VRL, and the repair line RL may include a conductive material including molybdenum (Mo), aluminum (Al), copper (Cu), and/or titanium (Ti), and may each have a single-layer or multi-layers including one or more of the aforementioned materials.

Referring to FIGS. 7 and 8, the first insulating layer 111 (e.g., see FIG. 5) may be disposed on the driving voltage line PL, the reference voltage line VRL, and the repair line RL. The first conductive pattern 1050, a 1-1 gate line GWLa, a second initializing voltage line VAL2, and a third initializing voltage line VAL3 may be disposed on the first insulating layer 111.

The first conductive pattern 1050 may have an isolated shape. The first conductive pattern 1050 may be disposed in correspondence with each of the first subpixel circuit area PCA1, the second subpixel circuit area PCA2, and the third subpixel circuit area PCA3. In other words, the first subpixel P1, the second subpixel P2, and the third subpixel P3 may include a 1-1 conductive pattern 1050a, a 1-2 conductive pattern 1050b, and a 1-3 conductive pattern 1050c that overlap with at least a portion of the driving voltage line PL. The 1-1 conductive pattern 1050a, the 1-2 conductive pattern 1050b, and the 1-3 conductive pattern 1050c may be arranged at (e.g., in or on) the same layer as each other (e.g., on the first insulating layer 111 in FIG. 5). At least a portion of the driving voltage line PL and at least a portion of the first conductive pattern 1050 may overlap with each other to form the second capacitor C2.

The 1-1 conductive pattern 1050a disposed in the first subpixel circuit area PCA1 may include a second electrode C22 of the second capacitor C2a overlapping with the first electrode C21a of the second capacitor C2a of the first subpixel P1. The 1-2 conductive pattern 1050b disposed in the second subpixel circuit area PCA2 may include a second electrode C22 of the second capacitor C2b overlapping with the first electrode C21b of the second capacitor C2b of the second subpixel P2. The 1-3 conductive pattern 1050c disposed in the third subpixel circuit area PCA3 may include a second electrode C22 of the second capacitor C2c overlapping with the first electrode C21c of the second capacitor C2c of the third subpixel P3.

The first conductive pattern 1050 may include the second lower electrode C12b of the first capacitor C1. According to an embodiment, the first conductive pattern 1050 may include a lower gate electrode (e.g., a 1-2 gate electrode) of a first transistor T1 (e.g., see FIG. 9) that overlaps with a first semiconductor layer A1 of the first transistor T1. The second electrode C22 of the second capacitor C2 and the second lower electrode C12b of the first capacitor C1 may be integrally provided, and may be connected to the second node N2 described above with reference to FIG. 4.

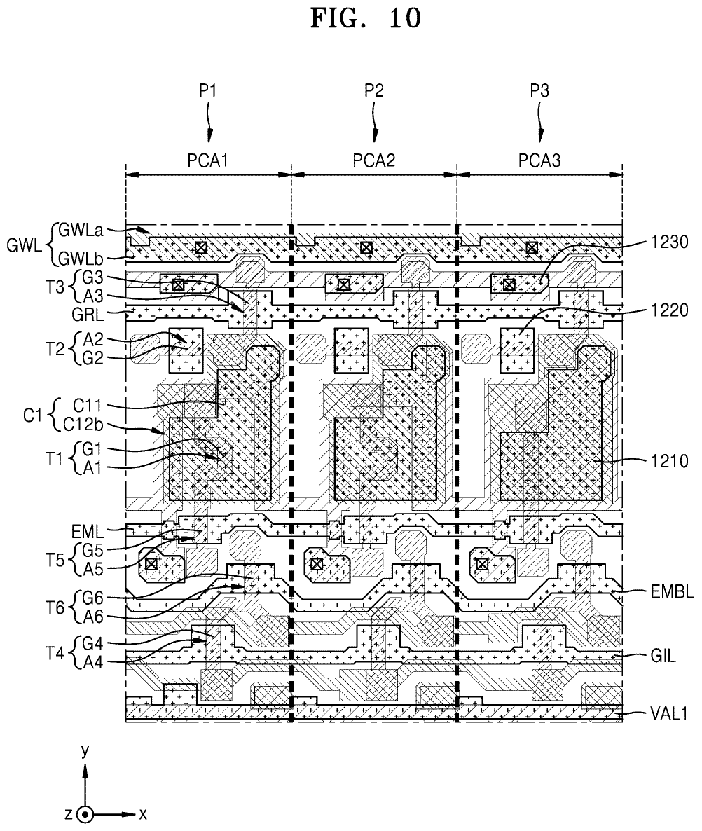

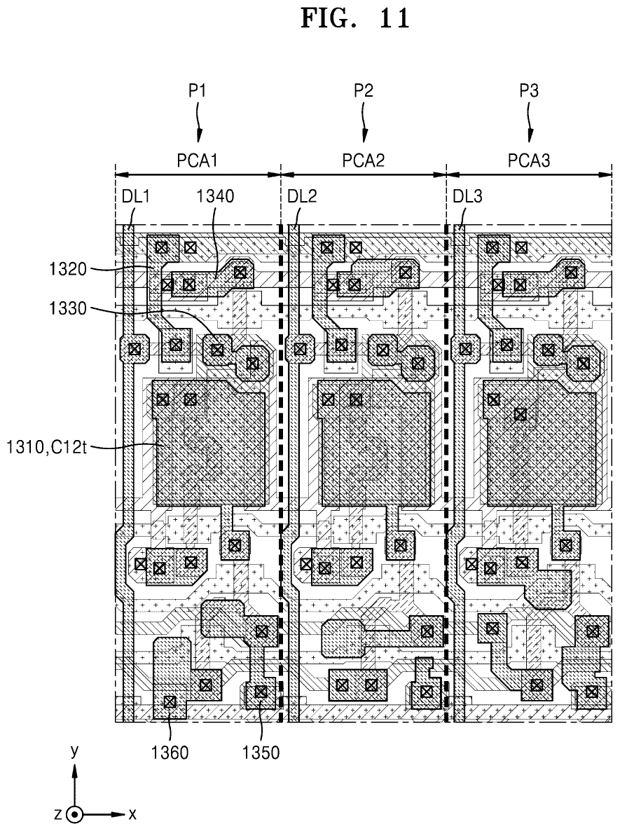

For example, because the first conductive pattern 1050 includes the second lower electrode C12b of the first capacitor C1 and the second electrode C22 of the second capacitor C2, and is electrically connected to a sixth semiconductor layer A1 (e.g., see FIG. 10) of a sixth transistor T6 and a first semiconductor layer A1 of a first transistor T1 by a first connection pattern 1310 (e.g., see FIG. 11), which will be described in more detail below, the first conductive pattern 1050 may be referred to as a first node electrode corresponding to the first node N1 described above with reference to FIG. 4.

Referring to FIGS. 8 and 12, the first conductive pattern 1050 disposed in each of the first, second, and third subpixel circuit areas PCA1, PCA2, and PCA3 may include first and second side surfaces SSa and SSb facing adjacent data lines DL. For example, the first conductive pattern 1050 may include the first side surface SSa and the second side surface SSb opposite to each other.

For example, the 1-1 conductive pattern 1050a disposed in the first subpixel circuit area PCA1 may include a first side surface SSa facing a first data line DL1, and a second side surface SSb facing a second data line DL2. For example, the 1-2 conductive pattern 1050b disposed in the second subpixel circuit area PCA2 may include a first side surface SSa facing the second data line DL2, and a second side surface SSb facing a third data line DL3. For example, the 1-3 conductive pattern 1050c disposed in the third subpixel circuit area PCA3 may include a first side surface SSa facing the third data line DL3, and a second side surface SSb facing a data line adjacent to the 1-3 conductive pattern 1050c in an unshown area (e.g., at a right side thereof in FIG. 12).

According to an embodiment, each of the first side surface SSa and the second side surface SSb of the 1-1 conductive pattern 1050a disposed in the first subpixel circuit area PCA1 may overlap with the first shielding portion SP1. For example, the first side surface SSa of the 1-1 conductive pattern 1050a may overlap with the first portion SP1a of the first shielding portion SP1. For example, the second side surface SSb of the 1-1 conductive pattern 1050a may overlap with the second portion SP1b of the first shielding portion SP1.

According to an embodiment, each of the first side surface SSa and the second side surface SSb of the 1-2 conductive pattern 1050b disposed in the second subpixel circuit area PCA2 may overlap with the second shielding portion SP2. For example, the first side surface SSa of the 1-2 conductive pattern 1050b may overlap with the first portion SP2a of the second shielding portion SP2. For example, the second side surface SSb of the 1-2 conductive pattern 1050b may overlap with the second portion SP2b of the second shielding portion SP2.

According to an embodiment, each of the first side surface SSa and the second side surface SSb of the 1-3 conductive pattern 1050c disposed in the third subpixel circuit area PCA3 may overlap with the third shielding portion SP3.

A distance DS1 between the first side surface SS1a of the first portion SP1a of the first shielding portion SP1 and the first data line DL1 may be less than a distance DS2 between the 1-1 conductive pattern 1050a and the first data line DL1. A distance DS3 between the second side surface SS1b of the second portion SP1b of the first shielding portion SP1 and the second data line DL2 may be less than a distance DS4 between the 1-1 conductive pattern 1050a and the second data line DL2.

Likewise, a distance between the first side surface SS1b of the first portion SP2a of the second shielding portion SP2 and the second data line DL2 may be less than a distance between the 1-2 conductive pattern 1050b and the second data line DL2. A distance between the second side surface SS2b of the second portion SP2b of the second shielding portion SP2 and the third data line DL3 may be less than a distance between the 1-2 conductive pattern 1050b and the third data line DL3.

A distance DS5 between the first side surface SS1c of the third shielding portion SP3 and the third data line DL3 may be less than a distance DS6 between the 1-3 conductive pattern 1050c and the third data line DL3.

According to an embodiment, in a plan view, as a shielding portion (e.g., the first, second, and third shielding portions SP1, SP2, and SP3) of the driving voltage line PL is formed to be disposed closer to a data line than (e.g., compared to) the first conductive pattern 1050, which is a first node electrode, a coupling between the first node electrode and the data line may be reduced, thereby improving a voltage swing of the data line, and thus, more stably transmitting a data signal. The shielding portion of the driving voltage line PL may be disposed under the first conductive pattern 1050 to reduce a coupling with the data line due to an electric field or a magnetic field formed under the first conductive pattern 1050.

Each of the 1-1 gate line GWLa, the second initializing voltage line VAL2, and the third initializing voltage line VAL3 may extend in the first direction (e.g., the x direction) to traverse the first subpixel circuit area PCA1, the second subpixel circuit area PCA2, and the third subpixel circuit area PCA3.

The 1-1 gate line GWLa may be disposed on one side of the first conductive pattern 1050, and the second initializing voltage line VAL2 and the third initializing voltage line VAL3 may each be disposed on another side (e.g., an opposite side) of the first conductive pattern 1050. For example, in a plan view, the 1-1 gate line GWLa may be disposed on an upper side of the first conductive pattern 1050, and the second initializing voltage line VAL2 and the third initializing voltage line VAL3 may each be disposed on a lower side of the first conductive pattern 1050. For example, the first conductive pattern 1050 may be located between the 1-1 gate line GWLa and the second initializing voltage line VAL2.

The first conductive pattern 1050, the 1-1 gate line GWLa, the second initializing voltage line VAL2, and the third initializing voltage line VAL3 may include the same material as each other. Each of the first conductive pattern 1050, the 1-1 gate line GWLa, the second initializing voltage line VAL2, and the third initializing voltage line VAL3 may include a conductive material including molybdenum (Mo), aluminum (Al), copper (Cu), and/or titanium (Ti), and may each have a single-layer or multi-layers including one or more of the aforementioned materials.

Referring to FIGS. 8 and 9, the second insulating layer 112 (e.g., see FIG. 5) may be disposed on the first conductive pattern 1050, the 1-1 gate line GWLa, the second initializing voltage line VAL2, and the third initializing voltage line VAL3. A semiconductor layer including first, second, and third semiconductor patterns 1110, 1120, and 1130 may be disposed on the second insulating layer 112.

Each of the first semiconductor pattern 1110, the second semiconductor pattern 1120, and the third semiconductor pattern 1130 may have an isolated shape. For example, the first semiconductor pattern 1110, the second semiconductor pattern 1120, and the third semiconductor pattern 1130 may be arranged to be spaced apart from each other. The first semiconductor pattern 1110, the second semiconductor pattern 1120, and the third semiconductor pattern 1130 may be arranged in correspondence with each of the first subpixel circuit area PCA1, the second subpixel circuit area PCA2, and the third subpixel circuit area PCA3.

The first semiconductor pattern 1110 may include a first semiconductor layer A1 and a fifth semiconductor layer A5. In other words, the first semiconductor layer A1 and the fifth semiconductor layer A5 may be integrally connected to each other. The second semiconductor pattern 1120 may include a second semiconductor layer A2 and a third semiconductor layer A3. In other words, the second semiconductor layer A2 and the third semiconductor layer A3 may be integrally connected to each other. The third semiconductor pattern 1130 may include a fourth semiconductor layer A4 and a sixth semiconductor layer A6. In other words, the fourth semiconductor layer A4 and the sixth semiconductor layer A6 may be integrally connected to each other.

The first semiconductor layer A1 may include a first channel region CH1 overlapping with a first gate electrode G1 of a first transistor T1 to be described in more detail below with reference to FIG. 10, a first source region S1 disposed on one side of the first channel region CH1, and a first drain region D1 disposed on another side of the first channel region CH1.

The second semiconductor layer A2 may include a second channel region CH2 overlapping with a second gate electrode G2 of a second transistor T2 to be described in more detail below with reference to FIG. 10, a second source region S2 disposed on one side of the second channel region CH2, and a second drain region D2 disposed on another side of the second channel region CH2.

The third semiconductor layer A3 may include a third channel region CH3 overlapping with a third gate electrode G3 of a third transistor T3 to be described in more detail below with reference to FIG. 10, a third source region S3 disposed on one side of the third channel region CH3, and a third drain region D3 disposed on another side of the third channel region CH3.

The fourth semiconductor layer A4 may include a fourth channel region CH4 overlapping with a fourth gate electrode G4 of a fourth transistor T4 to be described in more detail below with reference to FIG. 10, a fourth source region S4 disposed on one side of the fourth channel region CH4, and a fourth drain region D4 disposed on another side of the fourth channel region CH4.

The fifth semiconductor layer A5 may include a fifth channel region CH5 overlapping with a fifth gate electrode G5 of a fifth transistor T5 to be described in more detail below with reference to FIG. 10, a fifth source region S5 disposed on one side of the fifth channel region CH5, and a fifth drain region D5 disposed on another side of the fifth channel region CH5.

The sixth semiconductor layer A6 may include a sixth channel region CH6 overlapping with a sixth gate electrode G6 of a sixth transistor T6 to be described in more detail below with reference to FIG. 10, a sixth source region S6 disposed on one side of the sixth channel region CH6, and a sixth drain region D6 disposed on another side of the sixth channel region CH6.

The first, second, and third semiconductor patterns 1110, 1120, and 1130 may include the same material as each other. According to an embodiment, the first, second, and third semiconductor patterns 1110, 1120, and 1130 may include an oxide semiconductor material. For example, each of the first, second, and third semiconductor patterns 1110, 1120, and 1130 may include an oxide semiconductor material of at least one material selected from indium (In), gallium (Ga), tin (Sn), zirconium (Zr), vanadium (V), hafnium (Hf), cadmium (Cd), germanium (Ge), chromium

(Cr), titanium (Ti), aluminum (Al), cesium (Cs), cerium (Ce), and/or zinc (Zn). According to another embodiment, the first, second, and third semiconductor patterns 1110, 1120, and 1130 may include polysilicon or amorphous silicon.

Referring to FIGS. 7 and 9, in a plan view, the shielding portion of the driving voltage line PL disposed in each of the first, second, and third subpixel circuit areas PCA1, PCA2, and PCA3 may be spaced apart from the first channel area CH1 of the first semiconductor layer A1 of the first transistor T1 so as not to overlap with the first channel area CH1, or may overlap with the entire first channel area CH1 of the first semiconductor layer A1 of the first transistor T1.

For example, in a plan view, the first channel region CH1 of the first semiconductor layer A1 of the first transistor T1 disposed in the first subpixel circuit region PCA1 may be spaced apart from the first shielding portion SP1. For example, in a plan view, the first channel region CH1 of the first semiconductor layer A1 of the first transistor T1 disposed in the first subpixel circuit region PCA1 may be disposed between the first portion SP1a and the second portion SP1b of the first shielding portion SP1. For example, in a plan view, the first channel region CH1 of the first semiconductor layer A1 of the first transistor T1 disposed in the first subpixel circuit region PCA1 may be spaced apart from each of the first portion SP1a, the second portion SP1b, and the third portion SP1c of the first shielding portion SP1.

For example, in a plan view, the first channel region CH1 of the first semiconductor layer A1 of the first transistor T1 disposed in the second subpixel circuit region PCA2 may be spaced apart from the second shielding portion SP2. For example, in a plan view, the first channel region CH1 of the first semiconductor layer A1 of the first transistor T1 disposed in the second subpixel circuit region PCA2 may be disposed between the first portion SP2a and the second portion SP2b of the second shielding portion SP2. For example, in a plan view, the first channel region CH1 of the first semiconductor layer A1 of the first transistor T1 disposed in the second subpixel circuit region PCA2 may be spaced apart from each of the first portion SP2a, the second portion SP2b, and the third portion SP2c of the second shielding portion SP2.

For example, in a plan view, the entire first channel region CH1 of the first semiconductor layer A1 of the first transistor T1 disposed in the third subpixel circuit region PCA3 may overlap with the third shielding portion SP3.

In a comparative example, when a layer below the first semiconductor layer A1 includes a stepped portion in a region overlapping with the first channel region CH1 of the first semiconductor layer A1, the first semiconductor layer A1 may not be formed stably and may be electrically unstable. On the other hand, according to an embodiment, because the first shielding portion SP1 and the second shielding portion SP2 disposed below the first semiconductor layers A1 of the first subpixel P1 and the second subpixel P2 do not overlap with the first channel regions CH1, a step may not be formed in areas where the first channel regions CH1 are disposed, so that the first semiconductor layer A1 of the first transistor T1 may be formed more electrically stably. Likewise, as the third shielding portion SP3 disposed below the first semiconductor layer A1 of the first subpixel P1 and the second subpixel P2 overlaps with the entire first channel region CH1, a step may not be formed in an area where the first channel region CH1 is disposed, so that the first semiconductor layer A1 of the first transistor T1 may be formed more electrically stably.

Referring to FIGS. 9 and 10, the third insulating layer 113 (e.g., see FIG. 5) may be disposed on the first, second, and third semiconductor patterns 1110, 1120, and 1130. A second conductive pattern 1210, a third conductive pattern 1220, a fourth conductive pattern 1230, a 1-2 gate line GWLb, a second gate line GRL, a third gate line EML, a fourth gate line GIL, a fifth gate line EMBL, and a first initializing voltage line VAL1 may be disposed on the third insulating layer 113 (e.g., see FIG. 5).

Each of the second conductive pattern 1210, the third conductive pattern 1220, and the fourth conductive pattern 1230 may have an isolated shape. For example, the second conductive pattern 1210, the third conductive pattern 1220, and the fourth conductive pattern 1230 may be arranged to be spaced apart from each other. The second conductive pattern 1210, the third conductive pattern 1220, and the fourth conductive pattern 1230 may be arranged in correspondence with each of the first subpixel circuit area PCA1, the second subpixel circuit area PCA2, and the third subpixel circuit area PCA3.

The second conductive pattern 1210 may include the first gate electrode G1 of the first transistor T1 that overlaps with the first semiconductor layer A1 of the first transistor T1.

The second conductive pattern 1210 may overlap with the first conductive pattern 1050. The second conductive pattern 1210 may include the first electrode C11 of the first capacitor C1 that is connected to the first node N1 described above with reference to FIG. 4. The first electrode C11 of the first capacitor C1 may overlap with the second lower electrode C12b of the first capacitor C1. The first capacitor C1 may include the first electrode C11, the second lower electrode C12b, and the second upper electrode C12t, which is to be described in more detail below with reference to FIG. 11. For example, the first gate electrode G1 of the first transistor T1 and the first electrode C11 of the first capacitor C1 may be integrally provided.

The third conductive pattern 1220 may overlap with at least a portion of the second semiconductor pattern 1120. The third conductive pattern 1220 may include the second gate electrode G2 of the second transistor T2 that overlaps with the second semiconductor layer A2 of the second transistor T2.

At least a portion of the fourth conductive pattern 1230 may overlap with the reference voltage line VRL (e.g., see FIG. 7). The fourth conductive pattern 1230 may be connected to the reference voltage line VRL (e.g., see FIG. 7) through a contact hole that passes through at least one insulating layer interposed between the fourth conductive pattern 1230 and the reference voltage line VRL. The fourth conductive pattern 1230 may be connected to the fourth connection pattern 1340 to be described in more detail below with reference to FIG. 11. The fourth conductive pattern 1230 may be connected to the second semiconductor pattern 1120 (e.g., see FIG. 9) through the fourth connection pattern 1340.

Each of the 1-2 gate line GWLb, the second gate line GRL, the third gate line EML, the fourth gate line GIL, the fifth gate line EMBL, and the first initializing voltage line VAL1 may extend in the first direction (e.g., the x direction) to traverse the first subpixel circuit area PCA1, the second subpixel circuit area PCA2, and the third subpixel circuit area PCA3.

In a plan view, each of the 1-2 gate line GWLb and the second gate line GRL may be disposed on one side of the second conductive pattern 1210, and each of the third gate line EML, the fourth gate line GIL, the fifth gate line EMBL, and the first initializing voltage line VAL1 may be disposed on another side of the second conductive pattern 1210. For example, in a plan view, each of the 1-2 gate line GWLb and the second gate line GRL may be disposed on an upper side of the second conductive pattern 1210, and each of the third gate line EML, the fourth gate line GIL, the fifth gate line EMBL, and the first initializing voltage line VAL1 may be disposed on a lower side of the second conductive pattern 1210.

The 1-2 gate line GWLb may be disposed on the 1-1 gate line GWLa to overlap with the 1-1 gate line GWLa. The 1-1 gate line GWLa and the 1-2 gate line GWLb may be connected to each other through a contact hole that passes through at least one insulating layer interposed between the 1-1 gate line GWLa and the 1-2 gate line GWLb.

The second gate line GRL may overlap with at least a portion of the second semiconductor pattern 1120. The second gate line GRL may include the third gate electrode G3 of the third transistor T3 that overlaps with the third semiconductor layer A3 of the third transistor T3.

The third gate line EML may overlap with at least a portion of the first semiconductor pattern 1110. The third gate line EML may include the fifth gate electrode G5 of the fifth transistor T5 that overlaps with the fifth semiconductor layer A5 of the fifth transistor T5.

The fifth gate line EMBL may overlap with at least a portion of the third semiconductor pattern 1130. The fifth gate line EMBL may include the sixth gate electrode G6 of the sixth transistor T6 that overlaps with the sixth semiconductor layer A6 of the sixth transistor T6.

The fourth gate line GIL may overlap with at least a portion of the third semiconductor pattern 1130. The fourth gate line GIL may include the fourth gate electrode G4 of the fourth transistor T4 that overlaps with the fourth semiconductor layer A4 of the fourth transistor T4.

The second conductive pattern 1210, the third conductive pattern 1220, the fourth conductive pattern 1230, the 1-2 gate line, the second gate line GRL, the third gate line EML, the fourth gate line GIL, the fifth gate line EMBL, and the first initializing voltage line VAL1 may include the same material as each other. Each of the second conductive pattern 1210, the third conductive pattern 1220, the fourth conductive pattern 1230, the 1-2 gate line, the second gate line GRL, the third gate line EML, the fourth gate line GIL, the fifth gate line EMBL, and the first initializing voltage line VAL1 may include a conductive material including molybdenum (Mo), aluminum (Al), copper (Cu), and/or titanium (Ti), and may each have a single-layer or multi-layers including one or more of the aforementioned materials.

Referring to FIGS. 10 and 11, the fourth insulating layer 114 (e.g., see FIG. 5) may be disposed on the second conductive pattern 1210, the third conductive pattern 1220, the fourth conductive pattern 1230, the 1-2 gate line GWLb, the second gate line GRL, the third gate line EML, the fourth gate line GIL, the fifth gate line EMBL, and the first initializing voltage line VAL1. The first, second, and third data lines DL1, DL2, and DL3, the first connection pattern 1310, a second connection pattern 1320, a third connection pattern 1330, a fourth connection pattern 1340, a fifth connection pattern 1350, and a sixth connection pattern 1360 may be arranged on the fourth insulating layer 114.

The first connection pattern 1310, the second connection pattern 1320, the third connection pattern 1330, the fourth connection pattern 1340, the fifth connection pattern 1350, and the sixth connection pattern 1360 may be arranged in correspondence with each of the first subpixel circuit area PCA1, the second subpixel circuit area PCA2, and the third subpixel circuit area PCA3.

Each of the first, second, and third data lines DL1, DL2, and DL3 may extend in the second direction (e.g., the y direction) intersecting or crossing the first direction (e.g., the x direction). The first data line DL1 may be disposed in the first subpixel circuit area PCA1, and may be electrically connected to the subpixel circuit of the first subpixel P1. The second data line DL2 may be disposed in the second subpixel circuit area PCA2, and may be electrically connected to the subpixel circuit of the second subpixel P2. The third data line DL3 may be disposed in the third subpixel circuit area PCA3, and may be electrically connected to the subpixel circuit of the third subpixel P3.

For example, the first data line DL1 may be electrically connected to the second drain region D2 (e.g., see FIG. 9) of the second semiconductor layer A2 of the second transistor T2 included in the first subpixel P1 through a contact hole that passes through at least one insulating layer interposed between the second semiconductor layer A2 and the first data line DL1. For example, the second data line DL2 may be electrically connected to the second drain region D2 (e.g., see FIG. 9) of the second semiconductor layer A2 of the second transistor T2 included in the second subpixel P2 through a contact hole that passes through at least one insulating layer interposed between the second semiconductor layer A2 and the second data line DL2. For example, the third data line DL3 may be electrically connected to the second drain region D2 (e.g., see FIG. 9) of the second semiconductor layer A2 of the second transistor T2 included in the third subpixel P3 through a contact hole that passes through at least one insulating layer interposed between the second semiconductor layer A2 and the third data line DL3.

The first connection pattern 1310 may be connected to the first semiconductor pattern 1110 (e.g., see FIG. 9) through a contact hole that passes through at least one insulating layer interposed between the first connection pattern 1310 and the first semiconductor pattern 1110. For example, the first connection pattern 1310 may be connected to the first source region S1 (e.g., see FIG. 9) of the first semiconductor layer A1 of the first transistor T1 through the contact hole.

The first connection pattern 1310 may be connected to the third semiconductor pattern 1130 (e.g., see FIG. 9) through a contact hole that passes through at least one insulating layer provided between the first connection pattern 1310 and the first semiconductor pattern 1130. For example, the first connection pattern 1310 may be connected to the sixth drain region D6 (e.g., see FIG. 9) of the sixth semiconductor layer A6 of the sixth transistor T6 through the contact hole.

The first connection pattern 1310 may include the second upper electrode C12t of the first capacitor C1. The second upper electrode C12t of the first capacitor C1 may be connected to the second lower electrode C12b of the first capacitor C1 through a contact hole that passes through at least one insulating layer interposed between the second upper electrode C12t of the first capacitor C1 and the second lower electrode C12b of the first capacitor C1. The second upper electrode C12t of the first capacitor C1 may be disposed on the first electrode C11 of the first capacitor C1, and may overlap with the first electrode C11 of the first capacitor C1.

The first connection pattern 1310 may connect the first semiconductor layer A1, the sixth semiconductor layer A6, the second upper electrode C12t of the first capacitor C1, and the second lower electrode C12b of the first capacitor C1 to each other.

The second connection pattern 1320 may connect the second gate electrode G2 of the second transistor T2 to the 1-2 gate line GWLb. The second connection pattern 1320 may be connected to the 1-2 gate line GWLb through a contact hole that passes through at least one insulating layer interposed between the second connection pattern 1320 and the 1-2 gate line GWLb.

The third connection pattern 1330 may connect the second semiconductor pattern 1120 to the second conductive pattern 1210. The third connection pattern 1330 may connect the second drain region D2 (e.g., see FIG. 9) of the second semiconductor layer A2 of the second transistor T2, the third drain region D3 of the third semiconductor layer A3 of the third transistor T3, and the first gate electrode G1 of the first transistor T1 to each other. The third connection pattern 1330 may connect the second drain region D2 (e.g., see FIG. 9) of the second semiconductor layer A2 of the second transistor T2, the third drain region D3 of the third semiconductor layer A3 of the third transistor T3, and the first electrode C11 of the first capacitor C1 to each other.

The fourth connection pattern 1340 may be connected to the fourth conductive pattern 1230 and the second semiconductor pattern 1120 (e.g., see FIG. 9) through contact holes, and the fourth conductive pattern 1230 may be connected to the reference voltage line VRL. For example, the fourth connection pattern 1340 and the fourth conductive pattern 1230 may connect the reference voltage line VRL to the third semiconductor layer A3 of the third transistor T3.

When a defect occurs in a signal line or a voltage line included in the subpixel circuit, the fifth connection pattern 1350 may be a pattern that connects the repair line RL (e.g., see FIG. 7) and the subpixel circuit to each other. For example, the fifth connection pattern 1350 is connected to a repair pattern 1060 (e.g., see FIG. 8) and the third semiconductor pattern 1130, and when a defect occurs in the signal line or the voltage line, the repair pattern 1060 may be bonded with and connected to the repair line RL (e.g., see FIG. 7). The repair pattern 1060 may be disposed at (e.g., in or on) the same layer as the layer at (e.g., in or on) which the first conductive pattern 1050 is disposed.

The sixth connection pattern 1360 disposed in the first subpixel circuit area PCA1 may connect the first initializing voltage line VAL1 to the fourth source region S4 of the fourth semiconductor layer A4 of the fourth transistor T4 of the first subpixel circuit area PCA1. The sixth connection pattern 1360 disposed in the second subpixel circuit area PCA2 may connect the second initializing voltage line VAL2 to the fourth source region S4 of the fourth semiconductor layer A4 of the fourth transistor T4 of the second subpixel circuit area PCA2. The sixth connection pattern 1360 disposed in the third subpixel circuit area PCA3 may connect the third initializing voltage line VAL3 to the fourth source region S4 of the fourth semiconductor layer A4 of the fourth transistor T4 of the third subpixel circuit area PCA3.

The first, second, and third data lines DL1, DL2, and DL3, the first connection pattern 1310, the second connection pattern 1320, the third connection pattern 1330, the fourth connection pattern 1340, the fifth connection pattern 1350, the sixth connection pattern 1360, and the seventh connection pattern 1370 may include the same material as each other. The first, second, and third data lines DL1, DL2, and DL3, the first connection pattern 1310, the second connection pattern 1320, the third connection pattern 1330, the fourth connection pattern 1340, the fifth connection pattern 1350, and the sixth connection pattern 1360 may include a conductive material including molybdenum (Mo), aluminum (Al), copper (Cu), and/or titanium (Ti), and may each have a single-layer or multi-layers including one or more of the aforementioned materials.

Referring to FIGS. 11 and 12, a portion of each of the first data line DL1, the second data line DL2, and the third data line DL3 may overlap with the connection portion CP of the driving voltage line PL. According to an embodiment, because the first, second, and third shielding portions SP1, SP2, and SP3 may reduce a coupling between the first, second, and third data lines DL1, DL2, and DL3 and the first conductive pattern 1050, an area of the driving voltage line PL that overlaps with the first, second, and third data lines DL1, DL2, and DL3 may not be formed to be large. Accordingly, the area of a region where the connection portion CP overlaps with the first, second, and third data lines DL1, DL2, and DL3 may be minimized or reduced, which may lead to minimization or reduction of a parasitic capacitance. Accordingly, an RC relay in each subpixel circuit may be reduced.

In the embodiments described above with reference to FIGS. 6 through 12, the first shielding portion SP1 and the second shielding portion SP2 are each illustrated as having an omega shape, and the third shielding portion SP3 is illustrated as having an approximate polygonal shape. However, the present disclosure is not limited thereto. For example, each of the first shielding portion SP1, the second shielding portion SP2, and the third shielding portion SP3 may have an omega shape. For example, the first shielding portion SP1 may have an omega shape, and the second shielding portion SP2 and the third shielding portion SP3 may each have an approximate polygonal shape. As such, various suitable modifications may be made as needed or desired.

According to some embodiments of the present disclosure, a display apparatus having an improved display quality, and an electronic apparatus including the display apparatus may be provided. However, the aspects and features of the present disclosure are not limited thereto.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising:
a substrate comprising a display area comprising a plurality of pixels, and a non-display area located outside the display area;
a driving voltage line extending in a first direction on the substrate, and configured to transmit a driving voltage;
a conductive pattern on the driving voltage line, and at least partially overlapping with the driving voltage line;
a driving transistor comprising:
a first semiconductor layer on the conductive pattern, electrically connected to the conductive pattern, and comprising a channel region; and
a first gate electrode on the first semiconductor layer, and overlapping with the channel region;
a first capacitor comprising a first electrode integral with the first gate electrode, and a second lower electrode overlapping with the first electrode and included in the conductive pattern;
a second capacitor comprising a third electrode included in the driving voltage line, and a fourth electrode overlapping with the third electrode and included in the conductive pattern; and
a data line extending in a second direction perpendicular to the first direction,
wherein:
the driving voltage line comprises a shielding portion comprising a side surface facing the data line in a plan view; and
in a plan view, a distance between the side surface of the shielding portion and the data line is less than a distance between the conductive pattern and the data line.

2. The display apparatus of claim 1, wherein the first capacitor further comprises a second upper electrode on the first electrode and electrically connected to the second lower electrode.

3. The display apparatus of claim 1, wherein the third electrode is in at least a portion of the shielding portion.

4. The display apparatus of claim 1, wherein the shielding portion comprises:
a first portion extending in the second direction, and comprising a side surface facing the data line;
a second portion extending in the second direction, and spaced from the first portion in the first direction; and
a third portion extending in the first direction, and connecting the first portion to the second portion.

5. The display apparatus of claim 4, wherein a distance between the side surface of the first portion of the shielding portion facing the data line and the data line is less than a distance between the conductive pattern and the data line.

6. The display apparatus of claim 4, wherein, in a plan view, the shielding portion is spaced from the channel region of the first semiconductor layer.

7. The display apparatus of claim 4, wherein, in a plan view, the channel region of the first semiconductor layer is located between the first portion and the second portion of the shielding portion, and is spaced from the third portion of the shielding portion.

8. The display apparatus of claim 1, wherein the shielding portion overlaps with all of the channel region of the first semiconductor layer.

9. A display apparatus comprising:
a substrate comprising:
a display area comprising a first subpixel circuit of a first subpixel and a second subpixel circuit of a second subpixel that are adjacent to each other; and
a peripheral area outside the display area;
a driving voltage line configured to transmit a driving voltage, and extending in a first direction on the substrate to traverse a first subpixel circuit region comprising the first subpixel circuit and a second subpixel circuit region comprising the second subpixel circuit;
a first conductive pattern on the driving voltage line in the first subpixel circuit region and at least partially overlapping with the driving voltage line;
a second conductive pattern on the driving voltage line in the second subpixel circuit region and at least partially overlapping with the driving voltage line;
a first driving transistor in the first subpixel circuit region, and comprising:
a first semiconductor layer on the first conductive pattern, electrically connected to the first conductive pattern, and comprising a first channel region; and
a first gate electrode on the first semiconductor layer, and overlapping with the first channel region;
a second driving transistor in the second subpixel circuit region, and comprising:
a second semiconductor layer on the second conductive pattern, electrically connected to the second conductive pattern, and comprising a second channel region; and
a second gate electrode on the second semiconductor layer, and overlapping with the second channel region;
a first data line extending in a second direction perpendicular to the first direction, and configured to transmit a data voltage to the first subpixel circuit; and
a second data line extending in the second direction, and configured to transmit a data voltage to the second subpixel circuit,
wherein:
the driving voltage line comprises a first shielding portion in the first subpixel circuit region and comprising a first side surface facing the first data line, and a second side surface facing the second data line, in a plan view,
in a plan view, a distance between the first side surface of the first shielding portion and the first data line is less than a distance between the first conductive pattern and the first data line, and
in a plan view, the first shielding portion is spaced from the first channel region of the first semiconductor layer.

10. The display apparatus of claim 9, wherein a distance between the second side surface of the first shielding portion and the second data line is less than the distance between the first conductive pattern and the second data line.

11. The display apparatus of claim 9, wherein the driving voltage line further comprises a second shielding portion in the second subpixel circuit region and comprising a third side surface facing the second data line in a plan view, and a connection portion that connects the first shielding portion to the second shielding portion.

12. The display apparatus of claim 11, wherein a distance between the third side surface of the second shielding portion and the second data line is less than a distance between the second conductive pattern and the second data line.

13. The display apparatus of claim 11, wherein a portion of the second data line overlaps with the connection portion, and
wherein the second shielding portion overlaps with all of the second channel region of the second semiconductor layer.

14. The display apparatus of claim 9, wherein the first shielding portion comprises:
a first portion extending in the second direction, and comprising a side surface facing the first data line;
a second portion extending in the second direction, spaced from the first portion in the first direction, and comprising a side surface facing the second data line; and
a third portion extending in the first direction, and connecting the first portion to the second portion.

15. The display apparatus of claim 14, wherein, in a plan view, the first channel region of the first semiconductor layer is located between the first portion and the second portion of the first shielding portion, and is spaced from the third portion of the first shielding portion.

16. The display apparatus of claim 9, further comprising a first capacitor comprising a first electrode, and a second lower electrode overlapping with the first electrode,
wherein the first electrode and the first gate electrode are integral with each other, and the second lower electrode is in the first conductive pattern.

17. The display apparatus of claim 16, wherein the first capacitor further comprises a second upper electrode on the first electrode, and electrically connected to the second lower electrode.

18. The display apparatus of claim 9, further comprising a second capacitor comprising a third electrode, and a fourth electrode overlapping with the third electrode,
wherein the third electrode is in the first shielding portion, and the fourth electrode is in the first conductive pattern.

19. An electronic apparatus comprising:
a display apparatus; and
a housing accommodating the display apparatus,
wherein the display apparatus comprises:
a substrate comprising a display area comprising a plurality of pixels, and a non-display area outside the display area;
a driving voltage line extending in a first direction on the substrate, and configured to transmit a driving voltage;
a conductive pattern on the driving voltage line, and at least partially overlapping with the driving voltage line;
a driving transistor comprising:
a first semiconductor layer on the conductive pattern, electrically connected to the conductive pattern, and comprising a channel region; and
a first gate electrode on the first semiconductor layer, and overlapping with the channel region; and
a data line extending in a second direction perpendicular to the first direction,
wherein the driving voltage line comprises a shielding portion comprising a side surface facing the data line in a plan view, and
wherein, in a plan view, a distance between the side surface of the shielding portion and the data line is less than a distance between the conductive pattern and the data line.

20. The electronic apparatus of claim 19, further comprising a processor,
wherein the display apparatus further comprises:
a controller configured to receive a control signal from the processor, and output a power control signal based on the control signal; and
a power supply circuit configured to generate the driving voltage based on the power control signal of the controller, and
wherein the driving voltage line is electrically connected to the power supply circuit, and is configured to receive the driving voltage.
